(19) United States
(12) Patent Application Publication
(10) Pub. No.: US 2024/0234113 A1
(43) Pub. Date: Jul. 11, 2024

(54) PLASMA PROCESSING METHOD AND PLASMA PROCESSING APPARATUS

(71) Applicant: Tokyo Electron Limited, Tokyo (JP)

(72) Inventors: Takari YAMAMOTO, Miyagi (JP); Jun TAMURA, Miyagi (JP)

(73) Assignee: Tokyo Electron Limited, Tokyo (JP)

(21) Appl. No.: 18/398,217

(22) Filed: Dec. 28, 2023

(30) Foreign Application Priority Data
Dec. 28, 2022 (JP) 2022-211738

(51) Int. Cl. H01J 37/32

(52) U.S. Cl. CPC H01J 37/32981; H01J 37/32449; H01J 2237/334

(57) ABSTRACT

A plasma processing method includes (a) acquiring emission intensity of radicals generated by ionization of a processing gas within a chamber by a sensor that detects emission intensity within the chamber, in a plasma processing in which supplying of the processing gas to the chamber and exhausting of inside of the chamber are periodically repeated; (b) acquiring a target setting value of the emission intensity; and (c) calculating a processing condition of the plasma processing which brings the emission intensity closer to the setting value, based on the emission intensity acquired by (a) and the setting value acquired by (b).

### CROSS-REFERENCE TO RELATED APPLICATION

This application is based on and claims priority from Japanese Patent Application No. 2022-211738, filed on Dec. 28, 2022, with the Japan Patent Office, the disclosure of which is incorporated herein in its entirety by reference.

### TECHNICAL FIELD

The present disclosure relates to a plasma processing method and a plasma processing apparatus.

### BACKGROUND

Japanese Patent Laid-Open Publication No. 2016-027592 discloses “a plasma processing apparatus including a processing container, a gas supply system that supplies a gas into the processing container, a high frequency generation source that introduces high frequency waves for plasma generation into the processing container, and a control device that controls the gas supply system and the high frequency generation source.” The plasma processing apparatus is characterized in that the control device drives the high frequency generation source under a first energy condition in the first step, drives the high frequency generation source under a second energy condition in the second step, switches the type of gas to be supplied from the gas supply system into the processing container, prior to the switching time between the first step and the second step, and sets a gas flow rate in an initial period immediately after switching, to be larger than a gas flow rate in a stable period after the initial period elapses.

### SUMMARY

A plasma processing method according to one aspect of the present disclosure includes the steps (a), (b), and (c). In the step (a), in plasma processing in which supplying of a processing gas to a chamber and exhausting of inside of the chamber are periodically repeated, emission intensity of radicals generated by ionization of the processing gas within the chamber is acquired by a sensor that detects emission intensity within the chamber. In the step (b), a target setting value of the emission intensity is acquired. In the step (c), a processing condition of the plasma processing which brings the emission intensity closer to the setting value is calculated, based on the emission intensity acquired by the step (a) and the setting value acquired by the step (b).

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a view illustrating a configuration example of a capacitively coupled plasma processing apparatus.

FIGS. 2A to 2D are views illustrating an example of a periodic plasma process.

FIG. 3 is a view functionally illustrating the flow of optimization control by a processor according to a first embodiment.

FIG. 4 is a flow chart illustrating an example of the flow of control processing including the processing of a plasma processing method according to the first embodiment.

FIGS. 5A and 5B are views illustrating an example of results of optimization implementation of an operation amount according to the first embodiment.

FIGS. 6A to 6D are views illustrating an example of a conventional periodic plasma process.

FIGS. 7A to 7D are views illustrating an example of results of optimization implementation of the operation amount according to the first embodiment.

FIG. 8A is a view illustrating an example of impulse response waveforms.

FIG. 8B is a view illustrating an example of impulse response waveforms.

FIG. 8C is a view illustrating an example of impulse response waveforms.

FIGS. 9A to 9D are views illustrating an example of a conventional periodic plasma process.

FIGS. 10A to 10D are views illustrating an example of results of optimization implementation of an operation amount according to a second embodiment.

FIG. 11 is a view functionally illustrating the flow of processing of the processor according to the embodiment.

FIGS. 12A to 12C are views illustrating an example of correlation with OES emission intensity.

FIGS. 13A to 13C are views illustrating another example of correlation with OES emission intensity.

FIGS. 14A to 14D are views illustrating an example of a conventional periodic plasma process.

FIGS. 15A to 15D are views illustrating an example of results in a case where an operation amount U is optimized by changing B_{gas} and B_{apc} in accordance with the timing of HF power, in the embodiment.

### DETAILED DESCRIPTION

In the following detailed description, reference is made to the accompanying drawings, which form a part hereof. The illustrative embodiments described in the detailed description, drawings, and claims are not meant to be limiting. Other embodiments may be utilized, and other changes may be made without departing from the spirit or scope of the subject matter presented here.

Hereinafter, embodiments of a plasma processing method and a plasma processing apparatus will be described in detail with reference to drawings. The disclosed plasma processing method and plasma processing apparatus are not limited by the following embodiments.

In manufacturing of semiconductors, periodic plasma processes such as atomic layer etching (ALE) have been conventionally performed. In a periodic plasma process, a gas supply step of supplying a processing gas into a chamber, and a discharge step of discharging the processing gas supplied into the chamber or reaction products are frequently switched.

In a plasma process, an emission intensity detected inside a chamber by an optical emission spectroscopy (OES) sensor is used as an indirect indicator of a radical density that affects process results.

In the plasma process, a gas introduced into the chamber is ionized by plasma to generate radicals, and the generated radicals collide with a substrate. However, during the plasma process, the radicals are also consumed by, for example, deposits in the chamber, and the waveform of the emission intensity detected by the OES sensor is often not constant. That is, it is thought that the plasma process has become inefficient since the radical density is not constant. Therefore, there are expectations for techniques that increase the efficiency of the plasma process.

### First Embodiment

### [Device Configuration]

Hereinafter, an example of a plasma processing method and a plasma processing apparatus of the present disclosure will be described by using an embodiment. In the embodiment to be described below, as an example, a case will be described in which the plasma processing apparatus of the present disclosure is a plasma processing system having a system configuration. First, a first embodiment will be described.

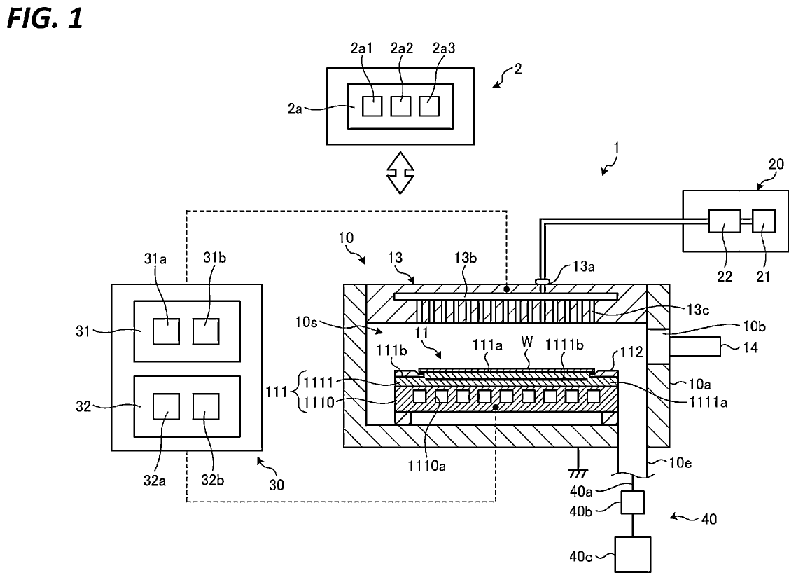

Hereinafter, a configuration example of the plasma processing system will be described. FIG. 1 is a view illustrating a configuration example of a capacitively coupled plasma processing apparatus.

The plasma processing system includes a capacitively coupled plasma processing apparatus 1 and a controller 2. The capacitively coupled plasma processing apparatus 1 includes a plasma processing chamber 10, a gas supply 20, a power supply 30 and an exhaust system 40. The plasma processing apparatus 1 also includes a substrate support 11 and a gas introduction section. The gas introduction section is configured to introduce at least one processing gas into the plasma processing chamber 10. The gas introduction section includes a shower head 13. The substrate support 11 is disposed within the plasma processing chamber 10. The shower head 13 is disposed above the substrate support 11. In one embodiment, the shower head 13 constitutes at least a part of the ceiling of the plasma processing chamber 10. The plasma processing chamber 10 has a plasma processing space 10s defined by the shower head 13, a side wall 10a of the plasma processing chamber 10, and the substrate support 11. The plasma processing chamber 10 has at least one gas supply port for supplying at least one processing gas to the plasma processing space 10s, and at least one gas outlet for discharging the gas from the plasma processing space. The plasma processing chamber 10 is grounded. The shower head 13 and the substrate support 11 are electrically insulated from the housing of the plasma processing chamber 10.

The plasma processing apparatus 1 is provided with a sensor 14 that monitors the emission intensity of plasma. The sensor 14 is, for example, an OES sensor. The side wall 10a of the plasma processing chamber 10 is provided with a transmission window 10b that transmits light. The transmission window 10b is composed of, for example, a quartz substrate, and has transparency to transmit light (visible light). The sensor 14 monitors the plasma emission intensity within the plasma processing chamber 10 through the transmission window 10b during plasma processing. For example, the sensor 14 detects the emission intensity of plasma for each wavelength. The sensor 14 outputs emission data indicating the detected emission intensity for each wavelength, to the controller 2. The sensor 14 may be disposed within the plasma processing chamber 10.

The substrate support 11 includes a main body 111 and a ring assembly 112. The main body 111 has a central region 111a for supporting a substrate W, and an annular region 111b for supporting the ring assembly 112. A wafer is an example of the substrate W. In plan view, the annular region 111b of the main body 111 surrounds the central region 111a of the main body 111. The substrate W is disposed on the central region 111a of the main body 111, and the ring assembly 112 is disposed on the annular region 111b of the main body 111 so as to surround the substrate W on the central region 111a of the main body 111. Therefore, the central region 111a is also called a substrate supporting surface for supporting the substrate W, and the annular region 111b is also called a ring supporting surface for supporting the ring assembly 112.

In one embodiment, the main body 111 includes a base 1110 and an electrostatic chuck 1111. The base 1110 includes a conductive member. The conductive member of the base 1110 may function as a lower electrode. The electrostatic chuck 1111 is disposed on the base 1110. The electrostatic chuck 1111 includes a ceramic member 1111a, and an electrostatic electrode 1111b disposed within the ceramic member 1111a. The ceramic member 1111a has the central region 111a. In one embodiment, the ceramic member 1111a also has the annular region 111b. Another member surrounding the electrostatic chuck 1111, such as an annular electrostatic chuck or an annular insulating member, may have the annular region 111b. In this case, the ring assembly 112 may be disposed on the annular electrostatic chuck or the annular insulating member, or may be disposed on both the electrostatic chuck 1111 and the annular insulating member. At least one RF/DC electrode coupled to a radio frequency (RF) power supply 31 and/or a direct current (DC) power supply 32 to be described below may be disposed within the ceramic member 1111a. In this case, at least one RF/DC electrode functions as the lower electrode. If a bias RF signal and/or a DC signal to be described below is supplied to at least one RF/DC electrode, the RF/DC electrode is also called a bias electrode. The conductive member of the base 1110 and at least one RF/DC electrode may function as a plurality of lower electrodes. Also, the electrostatic electrode 1111b may function as the lower electrode. Therefore, the substrate support 11 includes at least one lower electrode.

The ring assembly 112 includes one or more annular members. In one embodiment, one or more annular members include one or more edge rings and at least one cover ring. The edge ring is made of a conductive material or an insulating material, and the cover ring is made of an insulating material.

The substrate support 11 may include a temperature control module configured to control at least one of the electrostatic chuck 1111, the ring assembly 112, and the substrate, to a target temperature. The temperature control module may include a heater, a heat transfer medium, and a flow path 1110a, or a combination thereof. A heat transfer fluid such as brine or gas flows through the flow path 1110a. In one embodiment, the flow path 1110a is formed within the base 1110, and one or more heaters are disposed within the ceramic member 1111a of the electrostatic chuck 1111. The substrate support 11 may include a heat transfer gas supply configured to supply a heat transfer gas to the gap between the back surface of the substrate W and the central region 111a.

The shower head 13 is configured to introduce at least one processing gas from the gas supply 20 into the plasma processing space 10s. The shower head 13 has at least one gas supply port 13a, at least one gas diffusion chamber 13b, and a plurality of gas introduction ports 13c. The processing gas supplied to the gas supply port 13a is introduced into the plasma processing space 10s from the plurality of gas introduction ports 13c through the gas diffusion chamber 13b. The shower head 13 includes at least one upper electrode. In addition to the shower head 13, the gas introduction section may include one or more side gas injectors (SGIs) attached to one or more openings formed in the side wall 10a.

The gas supply 20 may include at least one gas source 21 and at least one flow controller 22. In one embodiment, the gas supply 20 is configured to supply at least one processing gas to the shower head 13, from each corresponding gas source 21 through each corresponding flow controller 22. Each flow controller 22 may include, for example, a mass flow controller or a pressure control-type flow controller. Further, the gas supply 20 may include one or more flow modulation devices that modulate the flow rate of at least one processing gas or make pulses of the flow rate.

The power supply 30 includes the RF power supply 31 coupled to the plasma processing chamber 10 via at least one impedance matching circuit. The RF power supply 31 is configured to supply at least one RF signal (RF power) to at least one lower electrode and/or at least one upper electrode. Accordingly, plasma is formed from at least one processing gas supplied to the plasma processing space 10s. Therefore, the RF power supply 31 may function as at least a part of a plasma generator configured to generate plasma from one or more processing gases, in the plasma processing chamber 10. When a bias RF signal is supplied to at least one lower electrode, a bias potential is generated in the substrate W, and ion components in the formed plasma can be drawn into the substrate W.

In one embodiment, the RF power supply 31 includes a first RF generator 31a and a second RF generator 31b. The first RF generator 31a is coupled to at least one lower electrode and/or at least one upper electrode via at least one impedance matching circuit, and is configured to generate a source RF signal (source RF power) for plasma generation. In one embodiment, the source RF signal has a frequency within a range of 10 MHz to 150 MHz. In one embodiment, the first RF generator 31a may be configured to generate source RF signals having different frequencies. One or more generated source RF signals are supplied to at least one lower electrode and/or at least one upper electrode.

The second RF generator 31b is coupled to at least one lower electrode via at least one impedance matching circuit, and is configured to generate a bias RF signal (bias RF power). The frequency of the bias RF signal may be the same as or different from the frequency of the source RF signal. In one embodiment, the bias RF signal has a frequency lower than the frequency of the source RF signal. In one embodiment, the bias RF signal has a frequency within a range of 100 kHz to 60 MHz. In one embodiment, the second RF generator 31b may be configured to generate bias RF signals having different frequencies. One or more generated bias RF signals are supplied to at least one lower electrode. In various embodiments, at least one of the source RF signal and the bias RF signal may be pulsed. Hereinafter, between the source RF signal and the bias RF signal, the source RF signal with a high frequency is also called HF (High Frequency), and the bias RF signal with a low frequency is also called LF (Low Frequency).

The power supply 30 may include the DC power supply 32 coupled to the plasma processing chamber 10. The DC power supply 32 includes a first DC generator 32a and a second DC generator 32b. In one embodiment, the first DC generator 32a is connected to at least one lower electrode, and is configured to generate a first DC signal. The generated first bias DC signal is applied to at least one lower electrode. In one embodiment, the second DC generator 32b is connected to at least one upper electrode, and is configured to generate a second DC signal. The generated second DC signal is applied to at least one upper electrode.

In various embodiments, at least one of the first and second DC signals may be pulsed. In this case, a sequence of voltage pulses is applied to at least one lower electrode and/or at least one upper electrode. The voltage pulses may have a pulse waveform of a rectangle, a trapezoid, a triangle or a combination thereof. In one embodiment, a waveform generator that generates a sequence of voltage pulses from DC signals is connected between the first DC generator 32a and at least one lower electrode. Therefore, the first DC generator 32a and the waveform generator constitute a voltage pulse generator. When the second DC generator 32b and the waveform generator constitute the voltage pulse generator, the voltage pulse generator is connected to at least one upper electrode. The voltage pulse may have a positive polarity or may have a negative polarity. The sequence of voltage pulses may include one or more positive voltage pulses and one or more negative voltage pulses within one period. The first and second DC generators 32a and 32b may be provided in addition to the RF power supply 31, or the first DC generator 32a may be provided instead of the second RF generator 31b.

The exhaust system 40 may be connected to, for example, a gas outlet 10e provided at the bottom of the plasma processing chamber 10. The exhaust system 40 includes an exhaust pipe 40a, an auto pressure controller (APC) valve 40b, and a vacuum pump 40c. The exhaust pipe 40a is connected to the gas outlet 10e. The exhaust pipe 40a is connected to the vacuum pump 40c. In the exhaust pipe 40a, the APC valve 40b is provided between the gas outlet 10e and the vacuum pump 40c. The vacuum pump 40c exhausts gases from the inside of the plasma processing chamber 10 through the exhaust pipe 40a. The vacuum pump 40c may include a turbo molecular pump, a dry pump or a combination thereof. The APC valve 40b adjusts the opening degree of the exhaust pipe 40a. In the exhaust system 40, the opening degree of the APC valve 40b is adjusted while gases are exhausted by the vacuum pump 40c, so that it is possible to adjust the pressure of the plasma processing chamber 10.

The controller 2 processes computer-executable instructions that cause the plasma processing apparatus 1 to execute various steps described in the present disclosure. The controller 2 may be configured to control each element of the plasma processing apparatus 1 so as to execute various steps described herein. In one embodiment, a part or all of the controller 2 may be included in the plasma processing apparatus 1. The controller 2 may include a processor 2a1, a storage 2a2, and a communication interface 2a3. The controller 2 is realized by, for example, a computer 2a. The processor 2a1 may be configured to read a program from the storage 2a2, and to execute the read program so as to perform various control operations. This program may be stored in the storage 2a2 in advance, or may be acquired via a medium if necessary. The acquired program is stored in the storage 2a2, and is read from the storage 2a2 by the processor 2a1 and then is executed. The medium may be various storage media readable by the computer 2a, or may be a communication line connected to the communication interface 2a3. The processor 2a1 may be a central processing unit (CPU). The storage 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN).

The storage 2a2 stores a control program (software) or a recipe for realizing various processes to be executed in the plasma processing apparatus 1, under the control of the processor 2a1. Various process conditions are stored in the recipe. For example, depending on a plasma process, the recipe stores start and end timings of each step of the plasma process. The recipe stores, for each step, setting values of gas flow rates of various gases to be used in the process, setting values for the pressure inside the plasma processing chamber 10, and setting values for the power or voltage of high frequency power such as HF or LF. In the present embodiment, depending on the plasma process, a target emission intensity is stored as a setting value in the recipe. As the control program or the recipe, those stored in, for example, a computer-readable computer recording medium (e.g., a hard disk, an optical disc such as a DVD, a flexible disk, a semiconductor memory, etc.) may be used. The control program or the recipe can also be transmitted from other devices at any time via, for example, a dedicated line and used online.

The processor 2a1 has an internal memory for storing programs or data, reads the control program stored in the storage 2a2, and executes processing of the read control program. The processor 2a1 controls each unit of the plasma processing apparatus 1. For example, the processor 2a1 controls each unit of the plasma processing apparatus 1 to perform a plasma process according to the recipe stored in the storage 2a2. For example, the processor 2a1 controls an exhaust device 104 and exhausts gases from the inside of the plasma processing chamber 10 so that the pressure within the plasma processing chamber 10 becomes a pressure value setting value stored in the recipe. The processor 2a1 controls the gas supply 20 and supplies various gases to be used in the process, into the plasma processing chamber 10 at gas flow rates as setting values stored in the recipe. The processor 2a1 controls the power supply 30 and supplies high frequency power such as HF or LF from the power supply 30 at the power or voltage as the setting value stored in the recipe.

Next, the operation of the plasma processing apparatus 1 will be described.

A substrate W is carried into the plasma processing chamber 10 via a loading/unloading port (not illustrated) by a transfer mechanism such as a transfer arm, and is placed on the substrate support 11.

The plasma processing apparatus 1 performs a periodic plasma process on the substrate W placed on the substrate support 11 under the control of the processor 2a1. In the present embodiment, a recipe including ALE processing is stored in the storage 2a2. The plasma processing apparatus 1 performs ALE on the substrate W according to the recipe, under the control of the processor 2a1.

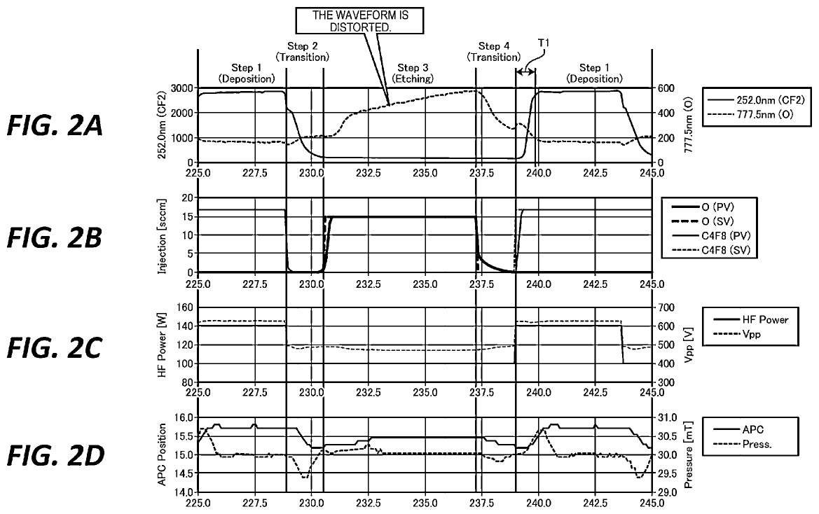

FIGS. 2A to 2D are views illustrating an example of a periodic plasma process. FIGS. 2A to 2D illustrate a case where an etching target film formed on the substrate W is etched by ALE. The etching target film is, for example, a silicon oxide film.

In the ALE, steps 1 to 4 are repeatedly performed until a predetermined condition is satisfied. The predetermined condition may be the number of times the steps 1 to 4 are repeated or may be an end condition for ending etching such as the thickness of a film to be etched.

In the step 1, while a deposition gas containing C₄F₈ gas is supplied, plasma is generated, and deposition is performed on the etching target film. In the step 1, an adsorbate based on C₄F₈ is physically adsorbed on the etching target film. In the step 2, the C₄F₈ gas is exhausted for transition to the following step 3.

In the step 3, while an etching gas containing an oxygen (O) gas such as O₂ gas is supplied, plasma is generated, and etching is performed on the etching target film. In the step 3, the adsorbate and the etching target film react with each other by using O₂ gas and the etching target film is etched. In the step 4, the oxygen gas is exhausted for transition to the step 1 again.

FIG. 2A illustrates waveforms of changes in the plasma emission intensity detected by the sensor 14. In the plasma process, a gas introduced into the chamber is ionized by plasma to generate radicals. For example, C₄F₈ gas is ionized to generate radicals such as CF₂. Oxygen (O) gas such as O₂ gas is ionized to generate radicals such as O. The plasma emission intensity differs between wavelengths depending on, for example, the gases or particles contained in the plasma, and the wavelength that correlates with the radical density in the plasma is also varied. For example, in plasma of C₄F₈ gas, the emission intensity at a wavelength of 252.0 nm correlates with the radical density of CF₂. In plasma of oxygen gas, the emission intensity at a wavelength of 777.5 nm correlates with the radical density of O. FIG. 2A illustrates changes in plasma emission intensities detected by the sensor 14, at wavelengths of 252.0 nm and 777.5 nm, in the steps 1 to 4. Hereinafter, the plasma emission intensity detected by the sensor 14 is also called “OES emission intensity.”

FIG. 2B illustrates waveforms of changes in a gas flow rate setting value SV and an actual gas flow rate PV. In FIG. 2B, the gas flow rate setting values SV of C₄F₈ gas and oxygen (O) gas are indicated by dotted lines, respectively. In FIG. 2B, the actual gas flow rates PV of C₄F₈ gas and oxygen (O) gas are indicated by solid lines, respectively. In the plasma processing apparatus 1, after supplying of gas from the gas supply 20 is started, until the gas reaches the inside of the plasma processing chamber 10, a dead time corresponding to passage through pipes occurs. For example, in FIGS. 2A and 2B, in the step 1 on the right, the dead time corresponds to the period TI from the timing when the setting value SV of C₄F₈ gas is increased, until C₄F₈ gas reaches the inside of the plasma processing chamber 10 and the emission intensity at the wavelength of 252.0 nm increases.

Such a dead time has been conventionally reflected on the recipe, manually by a process engineer. Otherwise, the recipe is created without taking the dead time into consideration.

FIG. 2C illustrates a waveform of a change in the power (HF Power) of source RF signal (HF) power supplied from the power supply 30, and a waveform of a change in the peak to peak value Vpp of the HF voltage V.

FIG. 2D illustrates a waveform of a change in the opening degree (APC Position) of the APC valve 40b, and a waveform of a change in the pressure within the plasma processing chamber 10. The exhaust volume of the APC valve 40b increases as the numerical value of the opening degree increases.

In the plasma processing apparatus 1, in the APC valve 40b as well, a dead time occurs after the opening degree of the APC valve 40b is changed, until the pressure within the plasma processing chamber 10 is changed. For example, in the steps 1 to 4, the dead time corresponds to the period until the pressure within the plasma processing chamber 10 is changed after the opening degree of the APC valve 40b is changed.

Meanwhile, the waveform of the emission intensity detected by the sensor 14 during the plasma process is often not constant. For example, as illustrated in FIG. 2A, in the step 3, the emission intensity waveform at the wavelength of 777.5 nm is distorted. In this way, if the emission intensity waveform is distorted, it is thought that the plasma process has become inefficient since the radical density is not constant.

Here, descriptions will be made on a state space model regarding the plasma process in the plasma processing apparatus 1. Hereinafter, in order to calculate a state change during the plasma process, timings at regular time intervals of the plasma process are sequentially numbered and are set as time steps. In the present embodiment, the time step is set as a timing having a period of 0.1 sec.

In the plasma process, a state equation of the state space model can be expressed as the following equation (1). The equation (1) is an equation for obtaining x(k+1) at a time step k+1 from x(k) at a time step k.

$$x ( k + 1 ) = A x ( k ) + {B}_{g a s} {u}_{gas} ( k - {n}_{τ , gas} ) + {B}_{a p c} {u}_{a p c} ( k - {n}_{τ , apc} ) \qquad ( 1 )$$

Here,
k is a time step.
x(k) is a vector of OES emission intensity at a wavelength corresponding to a gas at the time step k.
A is a parameter related to OES emission intensity.
n_{τ, gas} is a gas arrival dead time. In the present embodiment, n_{τ, gas} is the number of time steps corresponding to the gas arrival dead time.
u_{gas}(k-n_{τ, gas}) is a gas flow rate immediately before the gas arrival dead time n_{τ, gas} prior to the time step k.
B_{gas} is a parameter related to a gas flow rate.
n_{τ, apc} is a dead time of an APC opening degree operation. In the present embodiment, n_{τ, apc} is the number of time steps corresponding to the APC opening degree operation dead time. u_{apc}(k−n_{τ, apc}) is an APC opening degree immediately before the APC opening degree operation dead time n_{τ, apc} prior to the time step k.
B_{apc} is a parameter related to an APC opening degree operation.

In the plasma processing apparatus 1, the gas supplied from the gas supply 20 immediately before the dead time n_{τ, gas} prior to the time step k reaches the inside of the plasma processing chamber 10 and is formed into plasma. Thus, in the equation (1), the gas flow rate is set as u_{gas}(k-n_{τ, gas}). In the plasma processing apparatus 1, the APC opening degree operation immediately before the dead time n_{τ, apc} prior to the time step k affects the pressure within the plasma processing chamber 10 at the time step k. Therefore, in the equation (1), the APC opening degree is set as u_{apc}(k-n_{τ, apc}).

In the case of a state equation of OES emission intensities related to two gases (gas 1 and gas 2), the equation (1) can be expressed as the following equation (2) by using x(k), x(k+1), A, B_{gas}, u_{gas}(k−n_{τ, gas}), and B_{apc} as matrices.

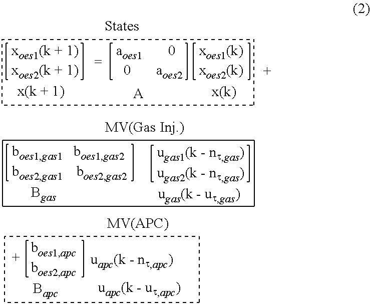

Here,

xₒₑₛ₁(k) is the OES emission intensity at a wavelength corresponding to the gas 1 at the time step k.

xₒₑₛ₂(k) is the OES emission intensity at a wavelength corresponding to the gas 2 at the time step k.

aₒₑₛ₁ and aₒₑₛ₂ are parameters that become elements of the matrix A. u_{gas1}(k−n_{τ, gas}) is the flow rate of the gas 1 at a point in time earlier than the gas arrival dead time n_{τ, gas} before the time step k.

u_{gas2}(k−n_{τ, gas}) is the gas flow rate of the gas 2 at a point in time earlier than the gas arrival dead time n_{τ, gas} before the time step k.

b_{oes1, gas1}, b_{oes1, gas2}, b_{oes2, gas1}, and b_{oes2, gas2} are parameters that become elements of the matrix B_{gas}.

b_{oes1, apc}, and b_{oes2, apc} are parameters that become elements of the matrix B_{apc}.

The equation (2) is determined depending on the gas 1 and the gas 2. In the present embodiment, one of C₄F₈ gas and oxygen gas is set as the gas 1, and the other of C₄F₈ gas and oxygen gas is set as the gas 2. For example, C₄F₈ gas is set as the gas 1, and oxygen gas is set as the gas 2. In this case, xₒₑₛ₁(k) is the OES emission intensity at a wavelength of 252.0 nm corresponding to C₄F₈ gas radicals at the time step k. xₒₑₛ₂(k) is the OES emission intensity at a wavelength of 777.5 nm corresponding to oxygen gas radicals at the time step k.

In the plasma processing apparatus 1, the gas arrival dead time n_{τ, gas} can be specified by measuring the time from the start of supplying of a gas from the gas supply 20 until the gas reaches the inside of the plasma processing chamber 10, and obtaining the number of time steps corresponding to the measured time. In the plasma processing apparatus 1, the APC opening degree operation dead time n_{τ, apc} can be specified by measuring the time from the change of the opening degree of the APC valve 40b until the pressure within the plasma processing chamber 10 is changed, and obtaining the number of time steps corresponding to the measured time.

The matrices A, B_{gas} and B_{apc} can be specified according to the plasma process. For example, changes in the flow rates of C₄F₈ gas, and oxygen gas, and changes in the OES emission intensities at wavelengths corresponding to C₄F₈ gas and oxygen gas are measured. aₒₑₛ₁, and aₒₑₛ₂ of the matrix A, b_{oes1, gas1} to b_{oes2, gas2} of the matrix B_{gas}, and b_{oes1, apc} and b_{oes2, apc} of the matrix B_{apc} can be specified by applying the measurement results to the equation (2) and searching for values that reduce an error. For example, changes in the flow rates of C₄F₈ gas and oxygen gas in the steps 1 to 4 of FIG. 2B, and changes in the OES emission intensities at wavelengths of 252.0 nm and 777.5 nm are applied to the equation (2) for each time step so that the matrices A, B_{gas} and B_{apc} are specified.

In the equation (2), from the OES emission intensities xₒₑₛ₁(k) and xₒₑₛ₂(k) of the two gases at the time step k, the OES emission intensities xₒₑₛ₁(k+1) and xₒₑₛ₂(k+1) of the two gases at the time step k+1 can be calculated. In the equation (2), from the calculated OES emission intensities xₒₑₛ₁(k+1) and xₒₑₛ₂(k+1) at the time step k+1, the OES emission intensities xₒₑₛ₁(k+2) and xₒₑₛ₂(k+2) of the two gases at the time step k+2 can be calculated. That is, by repeatedly using the equation (2), it is possible to calculate the OES emission intensities xₒₑₛ₁, and xₒₑₛ₂ at a plurality of time steps subsequent to the time step k.

The above-described equation (2) is a state equation of OES emission intensities related to C₄F₈ gas and oxygen gas. In the present embodiment, for the sake of simplification, assuming that the OES emission intensity in the state equation is the OES emission intensity to be observed, a prediction formula for the observation value is determined as in the following equation (3):

$$y ( k ) = x ( k ) \qquad ( 3 )$$

Here,

y(k) is a vector whose elements are the OES emission intensities to be observed at the time step k, at wavelengths corresponding to C₄F₈ gas and oxygen gas.

The equation (2) is temporally shifted to create a prediction formula for calculating a vector x for each time step, over a plurality of subsequent time steps. For example, assuming that a certain time step is a time step 0, a prediction formula is created so that from a vector x(0) of an OES emission intensity at the time step 0, vectors x(1) to x(m) of OES emission intensities at 1 to m subsequent time steps are calculated. The prediction formula can be expressed as a relational equation of a vector X, a matrix F, a matrix Gᵤ, and a vector U as in the following equation (4). The equation (4) is a prediction formula for prediction over a plurality of subsequent time steps when the state equation of the state space model is temporally shifted.

$$X = F x ( 0 ) + {G}_{u} U \qquad ( 4 )$$

Here,

The vector X is a vector whose elements are vectors x(1) to x(m) of OES emission intensities at 1 to m subsequent time steps, respectively, as in the following equation (5-1).

The matrix F is a matrix whose elements are the matrices A in which the multiplier is increased by 1 every two rows as in the following equation (5-2).

The vector U is a vector whose elements are vectors u(−n_{τ, gas}) to u(m−1) as in the following equation (5-3).

The vectors u(−n_{τ, gas}) to u(m−1) are vectors in which, at each time step, elements are the flow rate u_{gas1} of the gas 1 (C₄F₈ gas), the flow rate u_{gas2} of the gas 2 (oxygen gas), and the APC opening degree u_{apc}. For example, the vector u(−n_{τ, gas}) is a vector whose elements are the flow rate u_{gas1}(−n_{τ, gas}), the flow rate u_{gas2}(−n_{τ, gas}), and the APC opening degree u_{apc}(−n_{τ, gas}) at a time step earlier than the dead time n_{τ, gas} before the time step 0, as illustrated in the following equation (5-4).

The matrix Gᵤ is the same matrix as the following equation (6).

Δn_{τ} is a value obtained by subtracting the dead time n_{τ, apc} from the dead time n_{τ, gas}.

$$X = [ \begin{matrix}x ( 1 ) \\ x ( 2 ) \\ ⋮ \\ x ( {n}_{τ , gas} + 1 ) \\ ⋮ \\ x ( m )\end{matrix} ] \qquad ( 5 - 1 )$$

$$F = [ \begin{matrix}A \\ {A}^{2} \\ ⋮ \\ {A}^{{n}_{τ , gas} + 1} \\ ⋮ \\ {A}^{m}\end{matrix} ] \qquad ( 5 - 2 )$$

$$U = [ \begin{matrix}u ( - {n}_{τ , gas} ) \\ u ( - {n}_{τ , gas} + 1 ) \\ ⋮ \\ u ( 0 ) \\ ⋮ \\ u ( m - 1 )\end{matrix} ] \qquad ( 5 - 3 )$$

$$u ( - {n}_{τ , gas} ) = [ \begin{matrix}{u}_{gas 1} ( - {n}_{τ , gas} ) \\ {u}_{gas 2} ( - {n}_{τ , gas} ) \\ {u}_{apc} ( - {n}_{τ , gas} )\end{matrix} ] \qquad ( 5 - 4 )$$

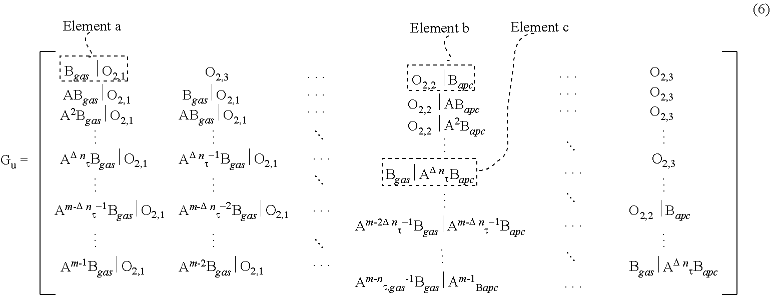

Each element of the matrix Gᵤ illustrated in the equation (6) is a matrix with two rows and three columns in which matrix elements illustrated for each are corresponding elements. For example, the element a is a matrix that is a combination of a 2×2 matrix B_{gas} and a 2×1 zero matrix as in the following equation (7-1). The element b is a matrix that is a combination of a 2×2 zero matrix and a 2×1 matrix B_{apc} as in the following equation (7-2). The element c is a matrix that is a combination of 2×2 B_{gas} and a 2×1 matrix A^{Δnτ}B_{apc} as in the following equation (7-3).

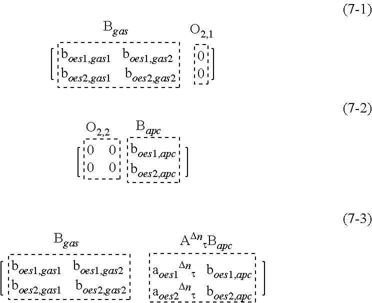

In the present embodiment, for the sake of simplification, it is assumed that the OES emission intensity in the state equation is the OES emission intensity to be observed. In this case, for the vector X in the above described equation (4), a prediction formula for the observation value is determined as in the following equation (8):

$$Y = X \qquad ( 8 )$$

Here,

THE vector Y is a vector of observation values in which elements are vectors y(k) of OES emission intensities to be observed for points in time of 1 to m subsequent time steps, respectively.

The vector U in the above-described equation (4) is a vector whose elements are vectors u(−n_{τ, gas}) to u(m−1) as illustrated in the equation (5-3). The vectors u(−n_{τ, gas}) to u(m−1) are vectors in which, at each time step, elements are the flow rate u_{gas1} of the gas 1 (C₄F₈ gas), the flow rate u_{gas2} of the gas 2 (oxygen gas), and the APC opening degree u_{apc}. The flow rate u_{gas1}, the flow rate u_{gas2}, and the APC opening degree u_{apc} can be operated by the processor 2a1. Therefore, the vector U can be set as an operation amount.

The processor 2a1 controls the plasma processing apparatus 1 by using the prediction formula illustrated in the above-described equation (4). The processor 2a1 calculates a processing condition for plasma processing which brings the emission intensity closer to a setting value. The processor 2a1 calculates a processing condition by using the prediction formula. The processor 2a1 controls the plasma processing apparatus 1 by using the calculated processing condition. For example, the processor 2a1 sets the vector U as the operation amount U, and calculates the optimum operation amount U as the processing condition by using the equation (4). Then, the processor 2a1 controls the plasma processing apparatus 1 by using the calculated optimum operation amount U.

A cost J(U) of changing the operation amount U is determined by using a vector Y, a vector SV, a matrix P, and a matrix Q as in the following equation (9-1).

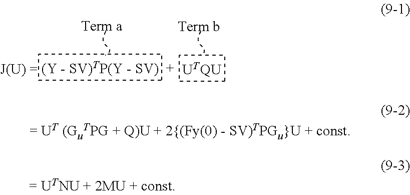

Here,

The vector Y is a vector of observation values in which elements are vectors y(k) of OES emission intensities to be observed for points in time of 1 to m subsequent time steps, respectively.

The vector SV is a vector whose elements are vectors r(1) to r(m) as in the following equation (10). For the vectors r(1) to r(m) of the vector SV, OES emission intensity setting values at 1 to m subsequent time steps are set.

The matrix P is a weight matrix of a setting value follow-up cost.

The matrix Q is a weight matrix of an operation amount cost.

$$SV = [ \begin{matrix}r ( 1 ) \\ r ( 2 ) \\ ⋮ \\ r ( {n}_{τ , gas} + 1 ) \\ ⋮ \\ r ( m )\end{matrix} ] \qquad ( 10 )$$

The term a in the equation (9-1) is a term for calculating the setting value follow-up cost. In the term a, a difference (Y-SV) between the vector Y and the vector SV is obtained, so that a deviation between the observation value and the setting value of OES emission intensity is obtained. The term a is set to be positive definite for (Y-SV)^{T}P(Y-SV) so that the setting value follow-up cost takes a positive value. The term b in the equation (9-1) is a term for calculating the operation amount cost. The term b is also set to be positive definite for U^{T}QU so that the operation amount cost takes a positive value. The matrix P, and the matrix Q are adjusted according to the weighting of the setting value follow-up cost and the operation amount cost, and are determined in advance so that the setting value follow-up cost, and the operation amount cost of the term b are positive.

Since Y=X in the equation (8), the equation (9-1) can be expressed as in the equation (9-2) when the equation (4) is put into the vector Y, and x(k) is replaced with y(k) by using the equation (3).

Then, the equation (9-2) can be expressed as in the equation (9-3) when the vector M is the following equation (11-1), and the matrix N is the following equation (11-2).

$$N = {G}_{u}^{T} P G + Q \qquad ( 11 - 1 )$$

$$M = {( F y ( 0 ) - S V )}^{T} P {G}_{u} \qquad ( 11 - 2 )$$

The matrix N is obtained by calculating the matrices Gᵤ, P, and Q, as in the equation (11-1). The matrices Gᵤ, P, and Q have no variables for elements, respectively and are constants. Thus, the elements of the matrix N are set as fixed values.

The vector M is obtained by calculating a matrix F, a vector y(0), a vector SV, a matrix P, and a matrix Gᵤ, as in the equation (11-2). The matrix F, the matrix P, and the matrix Gᵤ have no variables for elements respectively and are constants. The matrix y(0) is a matrix of OES emission intensity observation values at the time step 0, in which elements are set as fixed values. The vector SV is a vector whose elements are vectors r(1) to r(m) as in the equation (10). For the vectors r(1) to r(m) of the vector SV, OES emission intensity setting values for 1 to m time steps are set. Detailed settings of the vectors r(1) to r(m) will be described below. In this way, by setting the OES emission intensity setting values for 1 to m time steps in the vector SV, elements of the vector SV are set as fixed values. Thus, elements of the vector M are set as fixed values.

Therefore, the cost J(U) based on the equation (9-3) changes according to the operation amount U.

Next, descriptions will be made on the flow of calculating the optimum operation amount U.

The processor 2a1 calculates the operation amount U that minimizes the cost J(U), as the optimum operation amount U. For example, the processor 2a1 determines appropriate constraint conditions for the operation amount U, and calculates the operation amount U that minimizes the cost J(U), through quadratic programming.

One of 1 to m time steps is set as the current time step k. The current time step k is determined such that a past time step, which is earlier than a longer dead time between the dead time n_{τ, gas} and the dead time n_{τ, apc}, falls within a range of time steps 1 to m. In the present embodiment, m=10, the dead time n_{τ, gas} is 0.4 sec and corresponds to the longer dead time, and a time step of k=5 is the current time step.

In the vector SV, for the vectors r(1) to r(4) of time steps 1 to 4 earlier than the current time step (k=5), OES emission intensity setting values at each past time step are set. In the present embodiment, for the vectors r(1) to r(4), OES emission intensity setting values for wavelengths of 252.0 nm and 777.5 nm at each time step earlier than the current time step by 1 to 4 time steps are set. In the vector SV, for the vectors r(5) to r(10) of time steps 5 to 10 subsequent to the current time step (k=5), OES emission intensity setting values are set. In the present embodiment, for the vectors r(5) to r(10), OES emission intensity setting values for wavelengths of 252.0 nm and 777.5 nm at each time step subsequent to the current time step are set. For example, when a control is performed to make OES emission intensities constant at the time steps 5 to 10, target constant values are set for the vectors r(5) to r(10). That is, for the vectors r(1) to r(m), at each time step shifted by one time step before/after the current time step, the OES emission intensity setting value is set.

An optimization problem for minimizing the cost J(U) from the equation (9-3) is defined as in the following equation (12-1). The constraint conditions are defined as in the following equation (12-2) and the equation (12-3).

$$min J ( U ) = \frac{1}{2} {U}^{T} NU + MU \qquad ( 12 - 1 )$$

$$s . t . lb \leq U \leq ub \qquad ( 12 - 2 )$$

$${A}_{eq} U = {b}_{eq} \qquad ( 12 - 3 )$$

Here,

the matrix 1b is the lower limit of the operation amount U.

The vector ub is the upper limit of the operation amount U.

The matrix A_{eq} is a matrix that defines fixed elements in the operation amount U.

The vector b_{eq} is a vector that sets fixed elements in the operation amount U.

The equation (12-2) is an inequality constraint condition that defines the upper limit and the lower limit to which the operation amount U can be changed. The vector 1b is determined by minimum values of the flow rate u_{gas1}, the flow rate u_{gas2}, and the APC opening degree u_{apc} which can be changed in the plasma processing apparatus 1. In the present embodiment, minimum values of the flow rate u_{gas1}, the flow rate u_{gas2}, and the APC opening degree u_{apc} are set as zero. In the vector 1b, as in the following equation (13-1), each element is set as a zero vector. The vector 1b may be determined according to actually changeable lower limits of the flow rate u_{gas1}, the flow rate u_{gas2}, and the APC opening degree u_{apc}. The vector 1b may be determined as lower limits of operation amounts on the system instead of actual values of the flow rate u_{gas1}, the flow rate u_{gas2}, and the APC opening degree u_{apc}.

The vector ub is determined by maximum values of the flow rate u_{gas1}, the flow rate u_{gas2}, and the APC opening degree apc which can be changed in the plasma processing apparatus 1. In the present embodiment, a vector u whose elements are set as maximum values of the flow rate u_{gas1}, the flow rate u_{gas2}, and the APC opening degree u_{apc} is set as a vector uₘₐₓ. As in the following equation (13-2), the vector ub is a vector in which each element is the vector uₘₐₓ. The vector ub may be determined according to actually changeable upper limits of the flow rate u_{gas1}, the flow rate u_{gas2}, and the APC opening degree u_{apc}. The vector 1b may be determined as upper limits of operation amounts on the system instead of the actual values of the flow rate u_{gas1}, the flow rate u_{gas2}, and the APC opening degree u_{apc}.

$$lb = [ \begin{matrix}0 \\ 0 \\ ⋮ \\ 0\end{matrix} ] \qquad ( 13 - 1 )$$

$$ub = [ \begin{matrix}{u}_{max} \\ {u}_{max} \\ ⋮ \\ {u}_{max}\end{matrix} ] \qquad ( 13 - 2 )$$

The equation (12-3) is an equality constraint condition that defines fixed elements in the operation amount U.

The matrix A_{eq} is a matrix in which elements as diagonal elements corresponding to unchangeable steps are set as 1, and the others are set as 0 as in the following equation (14-1). For example, for elements of past time steps as unchangeable steps, elements as diagonal elements are set as 1, and the others are set as 0. In the present embodiment, at the current time step (k=5), time steps 1 to 4 earlier than the current time step are set as unchangeable steps. In this case, the matrix A_{eq} is a matrix in which elements as diagonal elements from the first row to the fourth row are set as 1, and the other elements are set as 0.

The vector b_{eq} is a matrix in which vectors u*(−n_{τ, gas}) to u*(−1) are set for elements corresponding to unchangeable steps as in the following equation (14-2). The vector u* is a vector u whose elements are the actual flow rate u_{gas1}, the actual flow rate u_{gas2}, and the actual APC opening degree u_{apc}. For example, the vector u*(−n_{τ, gas}) is a vector u whose elements are the flow rate u_{gas1}, the flow rate u_{gas2}, and the APC opening degree u_{apc} at a time step immediately before the dead time n_{τ, gas}. In the vectors u*(−n_{τ, gas}) to u*(−1), at each time step, the setting values of gas flow rates of C₄F₈ gas and oxygen gas and the opening degree of the APC valve 40b, which are actually set, are set as the flow rate u_{gas1}, the flow rate u_{gas2}, and the APC opening degree u_{apc}. In the present embodiment, at the current time step (k=5), the vectors u* are set for elements corresponding to the time steps 1 to 4 earlier than the current time step. In this case, the vector b_{eq} is a vector in which for elements from the first row to the fourth row, vectors u* whose elements are the actual flow rates u_{gas1}, the actual flow rates u_{gas2}, and the actual APC opening degrees u_{apc} at the time steps 1 to 4 are set. In this way, by determining the equality constraint condition, elements (vectors u) corresponding to zero portions of the vector b_{eq} become targets of optimization.

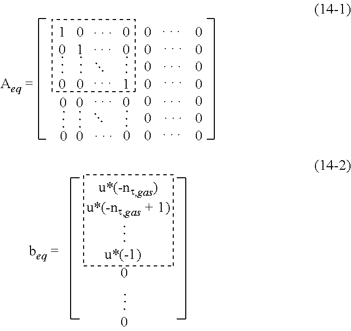

The processor 2a1 calculates the operation amount U that minimizes the cost J(U). For example, the processor 2a1 analyzes the optimization problem of the equation (12-1) by using the equation (12-2) and the equation (12-3) as constraint conditions, through quadratic programming, and calculates the operation amount U that minimizes the cost J(U). Accordingly, an optimized vector u is calculated for each element that is not a fixed element in the equation (12-3) of the operation amount U. In the present embodiment, an optimized vector u is calculated for each element for time steps 5 to 10 in the operation amount U.

The processor 2a1 controls the plasma processing apparatus 1 based on the calculated operation amount U. In the present embodiment, the processor 2a1 controls the plasma processing apparatus 1 based on the vector u corresponding to the current time step in the operation amount U. In the present embodiment, since it is the current time step (k=5), the plasma processing apparatus 1 is controlled based on the vector u(5) in the operation amount U. That is, at each time step, over a plurality of time steps subsequent to the current time step, the processor 2a1 calculates the respective processing conditions for the time steps. Then, at each time step, the processor 2a1 controls plasma processing by using a processing condition of the earliest time step among respective calculated processing conditions of time steps.

In the present embodiment, when a control is performed on the current time step (k=5), optimized vectors u for time steps 5 to 10 are calculated. In this way, not only for the current time step, but also for a plurality of subsequent time steps, respective optimized vectors u of the time steps are calculated, so that a vector u suitable for the current time step can be calculated in consideration of the plurality of subsequent time steps. The processor 2a1 controls the plasma processing apparatus 1 by using the vector u of the current time step among the vectors u calculated for the plurality of subsequent time steps. Accordingly, the processor 2a1 can control the plasma processing apparatus 1 in consideration of the plurality of subsequent time steps.

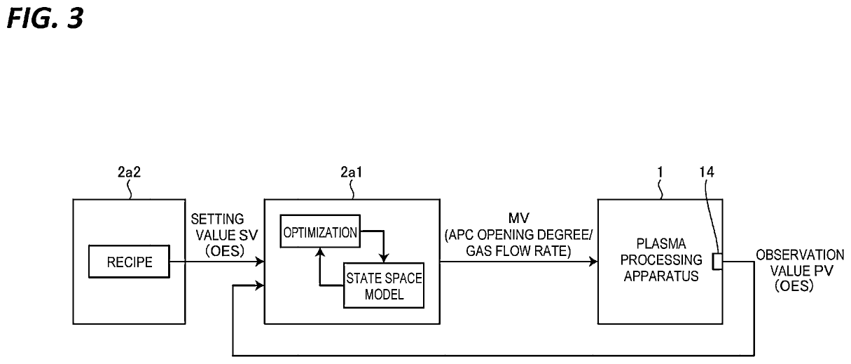

FIG. 3 is a view functionally illustrating the flow of optimization control by the processor 2a1 according to the first embodiment.

The processor 2a1 controls each unit of the plasma processing apparatus 1 according to the recipe stored in the storage 2a2 so as to perform the processing of a plasma process. According to the plasma process, target setting values of OES emission intensity are stored in the recipe. In the present embodiment, according to the plasma process, OES emission intensity setting values at wavelengths of 252.0 nm and 777.5 nm are stored in the recipe. When the processor 2a1 reads the recipe stored in the storage 2a2, the OES emission intensity setting values are input.

In the plasma processing apparatus 1, the sensor 14 detects the emission intensity of plasma for each wavelength, and outputs emission data indicating the detected emission intensity for each wavelength, to the processor 2a1.

The processor 2a1 stores the emission data input from the sensor 14. For example, the processor 2a1 stores OES emission intensities at wavelengths of 252.0 nm and 777.5 nm, for four most recent time steps.

The processor 2a1 controls the plasma processing apparatus 1 at the timing of each time step by using the above-described state space model illustrated in the equation (4). For example, the processor 2a1 sets the vector U as the operation amount U, and calculates the optimum operation amount U by using the equation (12-1) to which the equation (4) is applied.

For example, the processor 2a1 sets OES emission intensity setting values of the four most recent time steps, for vectors r(1) to r(4) of time steps 1 to 4 earlier than the current time step, in the vector SV. The processor 2a1 sets OES emission intensity setting values of six time steps subsequent to the current time step, for vectors r(5) to r(10) of time steps 5 to 10 subsequent to the current time step, in the vector SV. For example, at each time step shifted by one time step before/after the current time step, the OES emission intensity setting values are read from the recipe stored in the storage 2a2 and set for the vectors r(1) to r(m) by the processor 2a1. The processor 2a1 sets the matrix A_{eq} so that the time steps 1 to 4 earlier than the current time step become unchangeable steps. For elements in first to fourth rows of the vector b_{eq}, the processor 2a1 sets vectors u* in which the actual flow rates u_{gas1}, the actual flow rates u_{gas2}, and the actual APC opening degrees u_{apc} of the four most recent time steps are set.

Then, the processor 2a1 analyzes the optimization problem of the equation (12-1) by using the equation (12-2) and the equation (12-3) as constraint conditions, through quadratic programming, and calculates the operation amount U that minimizes the cost J(U). Accordingly, in the present embodiment, an optimized vector u is calculated for each element for time steps 5 to 10 in the operation amount U.

The processor 2a1 controls the plasma processing apparatus 1 based on the calculated operation amount U. In the present embodiment, the processor 2a1 controls the plasma processing apparatus 1 based on the vector u(5) corresponding to the current time step in the operation amount U.

The processor 2a1 repeats such processing at the timing of each time step to control a periodic plasma process such as ALE.

### [Plasma Processing Method]

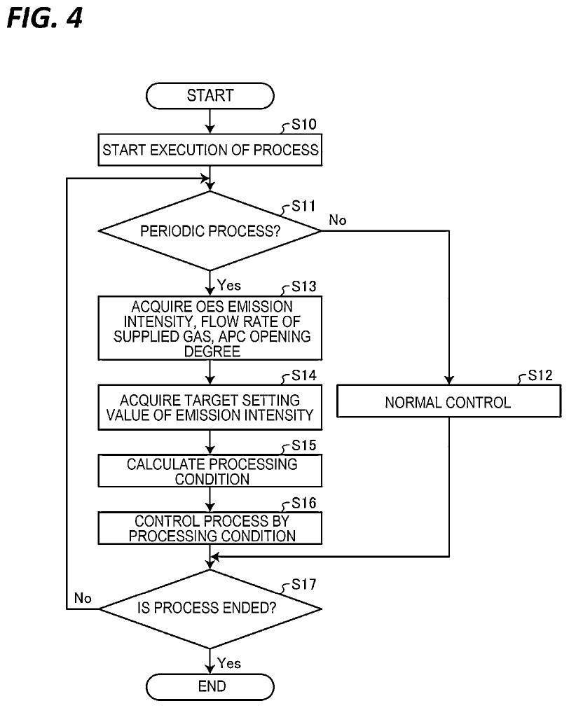

FIG. 4 is a flow chart illustrating an example of the flow of control processing including the processing of the plasma processing method according to the first embodiment. FIG. 4 mainly illustrates the flow of the processing of the plasma processing method included in the control processing. The processing illustrated in FIG. 4 is executed when plasma processing is performed in the plasma processing apparatus 1.

The processor 2a1 reads a recipe of plasma processing to be performed, from the storage 2a2, and starts execution of a plasma process according to the recipe (S10).

The processor 2a1 determines whether the plasma process being executed is a periodic plasma process (S11). For example, when a gas supply step of supplying a processing gas to the plasma processing chamber 10, and a discharge step of discharging the gas from the inside of the plasma processing chamber 10 are frequently switched, the processor 2a1 determines that the process is a periodic plasma process. For example, ALE is determined to be a periodic plasma process because the gas supply step (e.g., the steps 1 and 3) and the discharge step (e.g., the steps 2 and 4) are frequently switched. Setting information indicating whether a process is a periodic plasma process may be stored in the recipe. The processor 2a1 may determine whether a process is a periodic plasma process based on the setting information in the recipe.

When the plasma process being executed is not a periodic plasma process (S11: No), the processor 2a1 performs normal control according to the recipe so as to control each unit of the plasma processing apparatus 1 (S12), and proceeds to step S17 to be described below.

Meanwhile, when the plasma process being executed is a periodic plasma process (S11: Yes), the processor 2a1 acquires emission intensity of radicals generated by ionization of the processing gas within the plasma processing chamber 10. The processor 2a1 also acquires the gas flow rate of the processing gas supplied to the plasma processing chamber 10 and the opening degree of the APC valve 40b (step S13). For example, the processor 2a1 stores OES emission intensities at wavelengths of 252.0 nm and 777.5 nm, which are input from the sensor 14. For example, the processor 2a1 also stores setting values of gas flow rates of C₄F₈ gas and oxygen gas, and the opening degree of the APC valve 40b, which are actually set in the plasma process being performed. The processor 2a1 reads and acquires the OES emission intensities at wavelengths of 252.0 nm and 777.5 nm, the setting values of gas flow rates of C₄F₈ gas, and oxygen gas, and the opening degree of the APC valve 40b in the most recent predetermined period (four time steps).

The processor 2a1 acquires a target setting value of emission intensity (step S14). For example, the processor 2a1 acquires a target setting value of emission intensity for a period within a range of time steps 1 to m around the current time step in the vector SV, from the recipe. For example, in the present embodiment, from the recipe, the processor 2a1 acquires OES emission intensity setting values at each time step, from four time steps earlier than the current time step to six time steps subsequent to the current time step.

The processor 2a1 calculates a processing condition for plasma processing which brings the emission intensity closer to the setting value (step S15). For example, the processor 2a1 determines appropriate constraint conditions for the operation amount U, and calculates the optimum operation amount U that minimizes the cost J(U), through quadratic programming.

The processor 2a1 controls the plasma processing apparatus 1 based on the calculated processing condition (step S16). For example, the processor 2a1 controls the plasma processing apparatus 1 based on the calculated operation amount U. In the present embodiment, the processor 2a1 controls the plasma processing apparatus 1 based on the vector u(5) corresponding to the current time step in the operation amount U.

The processor 2a1 determines whether the plasma process has ended (S17). If the plasma process has not ended, the process proceeds to S11 described above. Meanwhile, if the plasma process has ended, the processing illustrated in the present flow chart is ended.

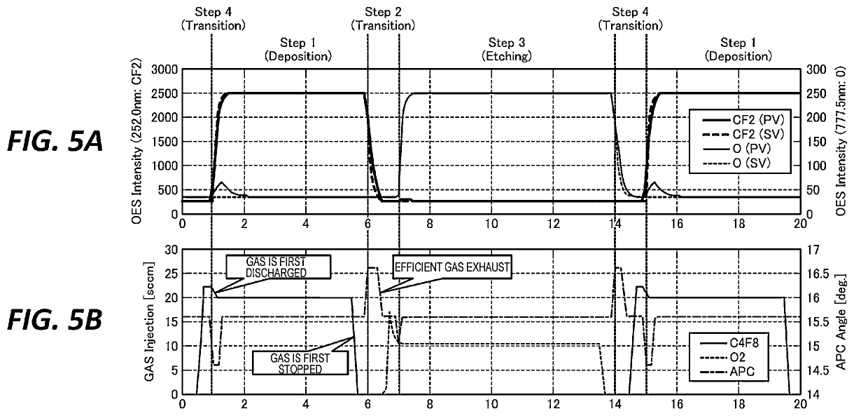

FIGS. 5A and 5B are views illustrating an example of results of optimization implementation of the operation amount U according to the first embodiment. FIGS. 5A and 5B illustrate the results of a simulation performed by a computer for a case where the above-described optimization of the operation amount U is performed for ALE.

FIGS. 5A and 5B illustrate steps 1 to 4 of ALE. In FIG. 5A, for the wavelength of 252.0 nm corresponding to C₄F₈ gas, and the wavelength of 777.5 nm corresponding to oxygen (O) gas, changes of OES emission intensity setting values SV set in optimization are indicated by dotted lines, respectively. Also, in FIG. 5A, for the wavelength of 252.0 nm corresponding to C₄F₈ gas and the wavelength of 777.5 nm corresponding to oxygen gas, changes of OES emission intensity observation values PV are indicated by solid lines in a case where ALE is performed with the optimized operation amount U. FIG. 5B illustrates a change of the setting values of gas flow rates of C₄F₈ gas and oxygen gas, and a change of the opening degree of the APC valve 40b, respectively. The opening degree of the APC valve 40b is indicated by an angle (APC Angle).

As a result of optimization of the operation amount U, in the step 1, the C₄F₈ gas is first discharged before the immediately preceding step 4 is ended, and the gas flow rate is also temporarily increased at the beginning. In the step 1, when the step 1 is started, the opening degree of the APC valve 40b is temporarily reduced. Accordingly, in the step 1, the plasma processing chamber 10 can be quickly filled with the C₄F₈ gas. As a result, in the step 1, the OES emission intensity at the wavelength of 252.0 nm quickly rises and then is stabilized at a constant emission intensity.

In the steps 1 to 2, the C₄F₈ gas is stopped before the end of the step 1, and the opening degree of the APC valve 40b is increased. Accordingly, in the step 2, the C₄F₈ gas can be quickly and efficiently exhausted. As a result, in the step 2, the OES emission intensity at the wavelength of 252.0 nm is also quickly decreased.

In the step 3, the oxygen gas is first discharged before the immediately preceding step 2 is ended, and the gas flow rate is also temporarily increased at the beginning. In the step 3, when the step 3 is started, the opening degree of the APC valve 40b is temporarily reduced. Accordingly, in the step 3, the plasma processing chamber 10 can be quickly filled with the oxygen gas. As a result, in the step 3, the OES emission intensity at the wavelength of 777.5 nm quickly rises and then is stabilized at a constant emission intensity.

In the steps 3 to 4, the oxygen gas is stopped before the end of the step 3, and the opening degree of the APC valve 40b is increased. Accordingly, in the step 4, the oxygen gas can be quickly and efficiently exhausted. As a result, in the step 4, the OES emission intensity at the wavelength of 777.5 nm is also quickly decreased.

Next, descriptions will be made on an example of results of optimization implemented in the first embodiment, through a comparison with a conventional method.

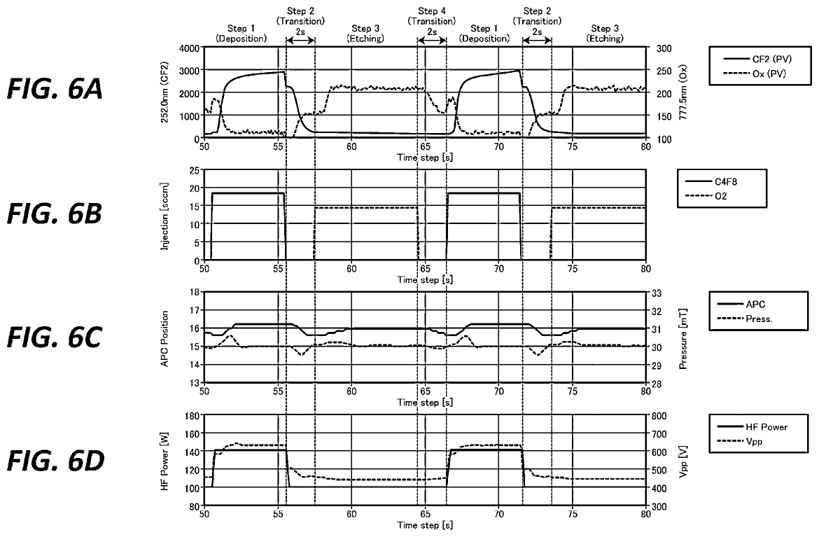

FIGS. 6A to 6D are views illustrating an example of a conventional periodic plasma process. FIGS. 6A to 6D illustrate a case where an etching target film formed on the substrate W is etched by ALE.

FIGS. 6A to 6D illustrate steps 1 to 4 of ALE. FIG. 6A illustrates a change of OES emission intensity observation values, for the wavelength of 252.0 nm corresponding to C₄F₈ gas and the wavelength of 777.5 nm corresponding to oxygen (O) gas. FIG. 6B illustrates a change of the setting values of gas flow rates of C₄F₈ gas and oxygen gas. FIG. 6C illustrates a waveform of a change in the opening degree of the APC valve 40b, and a waveform of a change in the pressure within the plasma processing chamber 10. FIG. 6D illustrates a waveform of a change in the power (HF Power) of source RF signal (HF) power supplied from the power supply 30, and a waveform of a change in the peak to peak value Vpp of the HF voltage V.

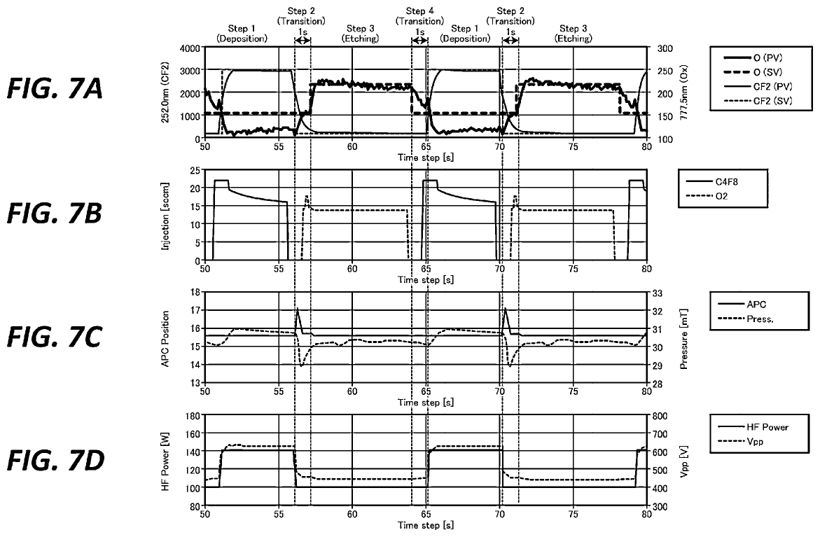

FIGS. 7A to 7D are views illustrating an example of results of optimization implementation of the operation amount U according to the first embodiment. FIGS. 7A to 7D illustrate a case where the optimization of the operation amount U is performed for the ALE process illustrated in FIGS. 6A to 6D. FIGS. 7A to 7D illustrate a case where the optimization of the operation amount U is performed by further adding constraint conditions that allow the opening degree of the APC valve 40b to be changed only during the period of the steps 2 and 4.

FIGS. 7A to 7D illustrate steps 1 to 4 of ALE. In FIG. 7A, for the wavelength of 252.0 nm corresponding to C₄F₈ gas and the wavelength of 777.5 nm corresponding to oxygen (O) gas, changes of OES emission intensity setting values SV set in optimization are indicated by dotted lines, respectively. Also, in FIG. 7A, for the wavelength of 252.0 nm corresponding to C₄F₈ gas and the wavelength of 777.5 nm corresponding to oxygen gas, changes of OES emission intensity observation values PV are indicated by solid lines in a case where ALE is performed with the optimized operation amount U. FIG. 7B illustrates a change of the setting values of gas flow rates of C₄F₈ gas and oxygen gas in the optimized operation amount U. FIG. 7C illustrates a waveform of a change in the opening degree of the APC valve 40b, and a waveform of a change in the pressure within the plasma processing chamber 10 in a case where ALE is performed with the optimized operation amount U. FIG. 7D illustrates a waveform of a change in the power (HF Power) of source RF signal (HF) power supplied from the power supply 30, and a waveform of a change in the peak to peak value Vpp of the HF voltage V in a case where ALE is performed.

In FIG. 6A, in the step 1, the waveform of the wavelength of 252.0 nm corresponding to C₄F₈ gas is not constant and is distorted. That is, the process has become inefficient since the radical density is not constant.

Meanwhile, in FIG. 7A, in the step 1, the waveform of the wavelength of 252.0 nm is close to the setting values SV, and is constant. Accordingly, the radical density becomes constant, and thus the process efficiency can be increased.

In FIGS. 6A to 6D, the period of each of the steps 2 and 4 was 2 sec, whereas in FIGS. 7A to 7D, the period of each of the steps 2 and 4 can be shortened to 1 sec through implementation of optimization. Accordingly, the periods of the steps 2 and 4 of ALE can be shortened, and thus the productivity of the ALE process can be increased.

### Second Embodiment

Next, a second embodiment will be described. The configuration of the plasma processing system according to the second embodiment is the same as the configuration in the first embodiment illustrated in FIG. 1, and thus descriptions thereof will be omitted.

Meanwhile, in the plasma process, due to occurrence of a disturbance, radicals may not be constant, and the waveform of OES emission intensity detected by the sensor 14 during the plasma process may not be constant in some cases. For example, in some cases, scavenging may occur in which radicals generated within the plasma processing chamber 10 are also consumed by deposits deposited within the plasma processing chamber 10, and the waveform of OES emission intensity during the plasma process is not constant.

Therefore, in the second embodiment, the disturbance is modeled, and a state space model including the disturbance model is created. Then, the state space model including the disturbance model is used to calculate a processing condition for plasma processing.

In a case where the disturbance model is included, the state equation of the state space model can be expressed as in the following equation (15):

$$x ( k + 1 ) = Ax ( k ) + {B}_{gas} {u}_{gas} ( k - {u}_{τ , gas} ) + {B}_{apc} {u}_{apc} ( k - {u}_{τ , apc} ) + {w}_{dv} ( k ) \qquad ( 15 )$$

Here,
w_{dv}(k) is the disturbance at a time step k.

The equation (15) is an equation in which a term of disturbance w_{dv}(k) is added to the above-described equation (1). In the case of a state equation of OES emission intensities related to two gases (gas 1 and gas 2), the equation (15) can be expressed as the following equation (16) by using x(k), x(k+1), A, B_{gas}, u_{gas}(k−n_{τ, gas}), B_{apc}, and w_{dv}(k) as matrices or vectors.

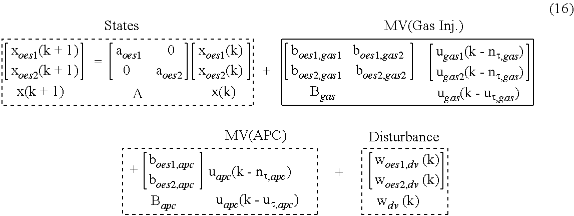

Here,

w_{oes1, dv}(k), and w_{oes2, dv}(k) are parameters that become elements of the vector w_{dv}(k).

w_{oes1, dv}(k) and w_{oes2, dv}(k) are determined according to the disturbance.

For example, in modelling a disturbance such as scavenging, w_{oes1, dv}(k), and w_{oes2, dv}(k) are determined as in the following equations (17-1) and (17-2):

$${w}_{oes 1 , dv} ( k ) = {x}_{oes 1} ( k - 1 ) - \hat{{x}_{oes 1}} ( k - 1 ) \qquad ( 17 - 1 )$$

$${w}_{oes 2 , dv} ( k ) = {x}_{oes 2} ( k - 1 ) - \hat{{x}_{oes 2}} ( k - 1 ) \qquad ( 17 - 2 )$$

Here,

xₒₑₛ₁(k−1) is an OES emission intensity observation value at the wavelength corresponding to the gas 1 at the time step k−1.

xₒₑₛ₂(k−1) is an OES emission intensity observation value at the wavelength corresponding to the gas 2 at the time step k−1.

x ₒₑₛ₁(k−1) is an OES emission intensity prediction value at the wavelength corresponding to the gas 1 at the time step k−1.

x ₒₑₛ₂(k−1) is an OES emission intensity prediction value at the wavelength corresponding to the gas 2 at the time step k−1.

x ₒₑₛ₁(k−1) and x ₑₒₛ₂(k−1) are calculated from OES emission intensity observation values at the time step k−2 by using, for example, the equation (1) or the equation (2).

That is, for each of w_{oes1, dv}(k) and w_{oes2, dv}(k), a difference between the observation value and the prediction value of OES emission intensity at the immediately preceding time step is set as a disturbance.

For example, in modelling a disturbance by the impulse response of a transfer function, w_{oes1, dv}(k) and w_{oes2, dv}(k) are determined as in the following equations (18-1) and (18-2):

$${w}_{oes 1 , dv} ( k ) = \{ \begin{matrix}{K}_{oes 1 , dv} exp [ - \frac{k Δ T - {τ}_{oes 1 , dv}}{{T}_{oes 1 , dv}} ] & ( t \geq {τ}_{oes 1 , dv} ) \\ 0 & ( t < {τ}_{oes 1 , dv} )\end{matrix} \qquad ( 18 - 1 )$$

$${w}_{oes 2 , dv} ( k ) = \{ \begin{matrix}{K}_{oes 2 , dv} exp [ - \frac{k Δ T - {τ}_{oes 2 , dv}}{{T}_{oes 2 , dv}} ] & ( t \geq {τ}_{oes 2 , dv} ) \\ 0 & ( t < {τ}_{oes 2 , dv} )\end{matrix} \qquad ( 18 - 2 )$$

Here,
K_{oes1, dv} is the gain for the gas 1 (magnitude of disturbance).
K_{oes2, dv} is the gain for the gas 2 (magnitude of disturbance).
T_{oes1, dv} is a time constant (decay time) for the gas 1.
T_{oes2, dv} is a time constant (decay time) for the gas 2.
T_{oes1, dv} is a dead time (time delay) for the gas 1.
T_{oes2, dv} is a dead time (time delay) for the gas 2.
ΔT is a sampling period.

It is possible to express waveforms of various impulse responses by changing the gains K_{oes1, dv}, and K_{oes2, dv}, the time constants T_{oes1, dv}, and T_{oes2, dv}, and the dead times T_{oes1, dv}, and T_{oes2, dv} in the equation (18-1) and the equation (18-2).

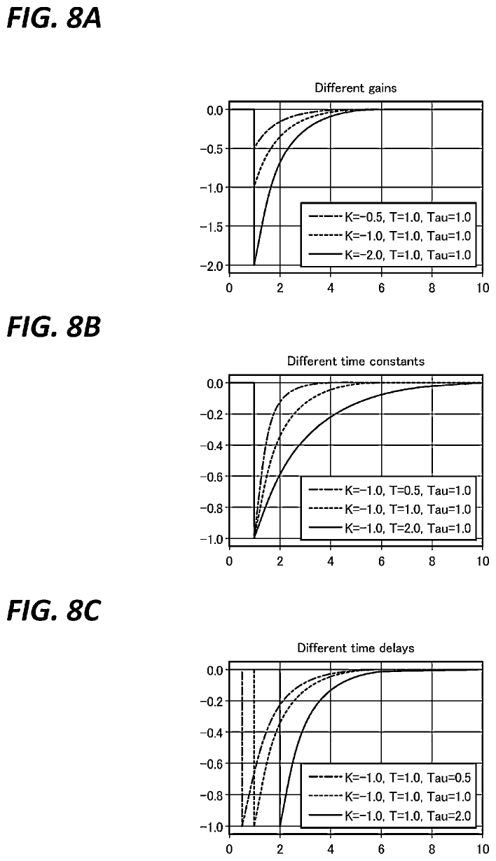

FIGS. 8A to 8C are views illustrating examples of impulse response waveforms. In the setting values illustrated in FIGS. 8A to 8C, the gains K_{oes1, dv}, and K_{oes2, dv} are set as K, the time constants T_{oes1, dv}, and T_{oes2, dv} are set as T, and the dead times T_{oes1, dv}, and T_{oes2, dv} are set as Tau. FIG. 8A illustrates waveforms of w_{oes1, dv}(k) and w_{oes2, dv}(k) in a case where T is fixed at 1.0, Tau is fixed at 1.0, and K is changed to −0.5, −1.5, and −2.0. FIG. 8B illustrates waveforms of w_{oes1, dv}(k) and w_{oes2, dv}(k) in a case where K is fixed at −1.0, Tau is fixed at 1.0, and T is changed to 0.5, 1.0, and 2.0. FIG. 8C illustrates waveforms of w_{oes1, dv}(k) and w_{oes2, dv}(k) in a case where K is fixed at −1.0, T is fixed at 1.0, and Tau is changed to 0.5, 1.0, and 2.0.

The prediction formula for the observation value is determined as in the following equation (19):

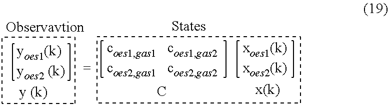

Here,

C is a matrix that transforms the vector y(k) and the vector x(k).

c_{oes1, gas1}, c_{oes1, gas2}, c_{oes2, gas1}, and c_{oes2, gas2} are parameters that become elements of the matrix C.

In the present embodiment, for the sake of simplification, the matrix C is used as a unit matrix, and then for the prediction formula for the observation value, y(k)=x(k) like in the first embodiment.

As in the first embodiment, the equation (16) is temporally shifted to create a prediction formula in which from a vector x(0) of an OES emission intensity at the time step 0, vectors x(1) to x(m) of OES emission intensities at 1 to m subsequent time steps are calculated. The prediction formula can be expressed as a relational equation of a vector X, a matrix F, a matrix Gᵤ, a vector U, a matrix G_{w}, and a vector W as in the following equation (20). The equation (20) is an equation in which G_{w}W is added to the above-described equation (4).

$$X = Fx ( 0 ) + {G}_{u} U + {G}_{w} w \qquad ( 20 )$$

Here,

The vector W is a vector whose elements are vectors w_{dv}(0) to w_{dv}(m-n_{τ, gas}), respectively, as in the following equation (21).

The matrix Gᵤ is the same matrix as the following equation (22-1).

The matrix G_{w} is the same matrix as the following equation (22-2).

$$W = [ \begin{matrix}w ( 0 ) \\ w ( 1 ) \\ ⋮ \\ w ( {n}_{τ , gas} ) \\ ⋮ \\ w ( m - {n}_{τ , gas} )\end{matrix} ] \qquad ( 21 )$$

$${G}_{u} = \qquad ( 22 - 1 )$$

$$[ \begin{matrix}{B}_{gas} \vert {O}_{2 , 1} & {O}_{2 , 3} & … & {O}_{2 , 2} \vert {B}_{apc} & … & {O}_{2 , 3} \\ {AB}_{gas} \vert {O}_{2 , 1} & {B}_{gas} \vert {O}_{2 , 1} & … & {O}_{2 , 2} \vert {AB}_{apc} & … & {O}_{2 , 3} \\ {A}^{2} {B}_{gas} \vert {O}_{2 , 1} & {AB}_{gas} \vert {O}_{2 , 1} & … & {O}_{2 , 2} \vert {A}^{2} {B}_{apc} & … & {O}_{2 , 3} \\ ⋮ & ⋮ & ⋱ & ⋮ & ⋱ & ⋮ \\ {A}^{Δ {n}_{τ}} {B}_{gas} \vert {O}_{2 , 1} & {A}^{Δ {n}_{τ} - 1} {B}_{gas} \vert {O}_{2 , 1} & … & \begin{matrix}{B}_{gas} \vert \\ {A}^{Δ {n}_{τ}} {B}_{apc}\end{matrix} & … & {O}_{2 , 3} \\ ⋮ & ⋮ & ⋱ & ⋮ & ⋱ & ⋮ \\ \begin{matrix}{A}^{m - Δ {n}_{τ} - 1} {B}_{gas} \vert \\ {O}_{2 , 1}\end{matrix} & \begin{matrix}{A}^{m - Δ {n}_{τ} - 2} {B}_{gas} \vert \\ {O}_{2 , 1}\end{matrix} & … & \begin{matrix}{A}^{m - 2 Δ {n}_{τ} - 1} {B}_{gas} \vert \\ {A}^{m - Δ {n}_{τ} - 1} {B}_{apc}\end{matrix} & … & \begin{matrix}{O}_{2 , 2} \vert \\ {B}_{apc}\end{matrix} \\ ⋮ & ⋯ & ⋱ & ⋮ & ⋱ & ⋮ \\ {A}^{m - 1} {B}_{gas} \vert {O}_{2 , 1} & {A}^{m - 2} {B}_{gas} \vert {O}_{2 , 1} & … & \begin{matrix}{A}^{m - {n}_{τ , gas} - 1} {B}_{gas} \vert \\ {A}^{m - 1} {B}_{apc}\end{matrix} & … & \begin{matrix}{B}_{gas} \vert \\ {A}^{Δ {n}_{τ}} {B}_{apc}\end{matrix}\end{matrix} ]$$

$${G}_{w} = [ \begin{matrix}I & O & … & O & … & O \\ A & I & … & O & … & O \\ ⋮ & ⋮ & ⋱ & ⋮ & ⋱ & ⋮ \\ {A}^{{n}_{τ , gas} + 1} & {A}^{{n}_{τ , gas}} & … & I & … & O \\ ⋮ & ⋮ & ⋱ & ⋮ & ⋱ & ⋮ \\ {A}^{m - 1} & {A}^{m - 2} & … & {A}^{m - {n}_{τ , gas} - 1} & … & I\end{matrix} ] \qquad ( 22 - 2 )$$

The prediction formula for the observation value is determined as in the following equations (23-1) and (23-2):

$$Y = CX \qquad ( 23 - 1 )$$

$${[ \begin{matrix}y ( 1 ) \\ y ( 2 ) \\ ⋮ \\ y ( m )\end{matrix} ]}_{Y} = [ \begin{matrix}C & 0 & … & 0 \\ 0 & C & … & 0 \\ ⋮ & ⋮ & ⋱ & ⋮ \\ 0 & 0 & … & C\end{matrix} ] {[ \begin{matrix}x ( 1 ) \\ x ( 2 ) \\ ⋮ \\ x ( m )\end{matrix} ]}_{X} \qquad ( 23 - 2 )$$

In the present embodiment, for the sake of simplification, the matrix C is used as a unit matrix, and then vector Y=vector X like in the first embodiment.

The vector U in the equation (20) is set as the operation amount U. A cost J(U) of changing the operation amount U is determined by using a vector Y, a vector SV, a matrix P, and a matrix Q as in the following equation (24-1). When the equation (20) is put into the vector X, the equation (24-1) can be expressed as the equation (24-2). In the equation (24-2), the portion of a term c is added to the above-described equation (9-2).

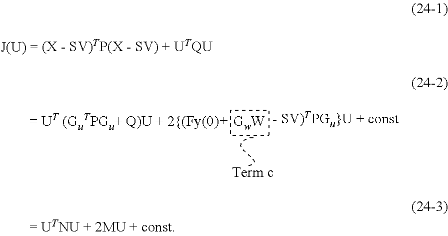

Then, the equation (24-2) can be expressed as the equation (24-3), when the matrix N is the following equation (25-1), and the vector M is the following equation (25-2).

$$N = {G}_{u}^{T} {PG}_{u} + Q \qquad ( 25 - 1 )$$

$$M = {( Fx ( 0 ) + {G}_{w} W - SV )}^{T} {PG}_{u} \qquad ( 25 - 2 )$$

The matrix N is obtained by calculating the matrix Gᵤ, the matrix P, and the matrix Q as in the equation (25-1). The matrix Gᵤ, the matrix P, and the matrix Q have no variables for elements, respectively, and are constants. Thus, the elements of the matrix N are set as fixed values.

The vector M is obtained by calculating the matrix F, the vector x(0), the matrix G_{w}, the vector W, the vector SV, the matrix P, and the matrix Gᵤ as in the equation (25-2). The matrix F, the matrix P, the matrix Q, the matrix G_{w}, and the vector W have no variables for elements, respectively, and are constants. The vector x(0) is a vector of OES emission intensity observation values at the time step 0, in which elements are set as fixed values. The vector SV is a vector whose elements are vectors r(1) to r(m) as in the above-described equation (10). For the vectors r(1) to r(m) of the vector SV, at each time step shifted by one time step before/after the current time step, OES emission intensity setting values are set like in the first embodiment. In this way, by setting the OES emission intensity setting values in the vector SV, elements of the vector SV are set as fixed values. Thus, elements of the vector M are set as fixed values.

Therefore, in the second embodiment as well, from the equation (24-3), the cost J(U) changes depending on the operation amount U. Therefore, in the second embodiment, similarly to the first embodiment, an optimization problem for minimizing the cost J(U) from the equation (24-3) can be defined as in the above-described equation (12-1). In the second embodiment, similarly to the first embodiment, by setting appropriate constraint conditions for the operation amount U, it is possible to calculate the operation amount U that minimizes the cost J(U), through quadratic programming.

The processor 2a1 calculates a processing condition for plasma processing which brings the emission intensity closer to the setting value. The processor 2a1 calculates the processing condition by using the state space model. For example, the processor 2a1 sets the vector U as the operation amount U, and calculates the optimum operation amount U, as the processing condition, by using the equation (20). For example, the processor 2a1 analyzes the optimization problem of the equation (12-1) by using the equation (12-2) and the equation (12-3) as constraint conditions, through quadratic programming, and calculates the operation amount U that minimizes the cost J(U). Accordingly, an optimized vector u is calculated for each element that is not a fixed element in the equation (12-3) for the operation amount U. For example, like in the first embodiment, an optimized vector u is calculated for each element for time steps 5 to 10 in the operation amount U.

The processor 2a1 controls the plasma processing apparatus 1 based on the calculated operation amount U. For example, like in the first embodiment, the processor 2a1 controls the plasma processing apparatus 1 based on the vector u(5) corresponding to the current time step in the operation amount U.

The processor 2a1 repeats such processing at the timing of each time step to control a periodic plasma process such as ALE.

Next, descriptions will be made on an example of results of optimization implemented in the second embodiment, through a comparison with a conventional method.

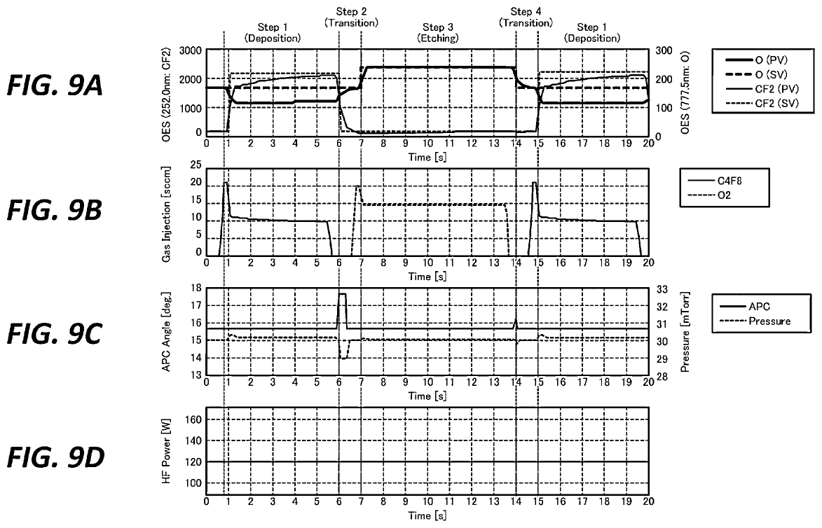

FIGS. 9A to 9D are views illustrating an example of a conventional periodic plasma process. FIGS. 9A to 9D illustrate a case where an etching target film formed on the substrate W is etched by ALE.

FIGS. 9A to 9D illustrate steps 1 to 4 of ALE. In FIG. 9A, for the wavelength of 252.0 nm corresponding to C₄F₈ gas and the wavelength of 777.5 nm corresponding to oxygen (O) gas, changes of OES emission intensity observation values PV are indicated by solid lines, respectively. Also, in FIG. 9A, for the wavelength of 252.0 nm and the wavelength of 777.5 nm, changes of OES emission intensity setting values SV are indicated by dotted lines, respectively. FIG. 9B illustrates a change of the setting values of gas flow rates of C₄F₈ gas and oxygen gas. FIG. 9C illustrates a waveform of a change in the opening degree of the APC valve 40b, and a waveform of a change in the pressure within the plasma processing chamber 10. The opening degree of the APC valve 40b is indicated by an angle (APC Angle). FIG. 9D illustrates a waveform of a change in the power (HF Power) of source RF signal (HF) power supplied from the power supply 30.

In FIGS. 9A to 9D, in the step 1, scavenging occurs in which radicals generated within the plasma processing chamber 10 are also consumed by deposits deposited within the plasma processing chamber 10, and OES emission intensity observation values PV gradually increase to setting values SV. That is, the process has become inefficient since the radical density is not constant.

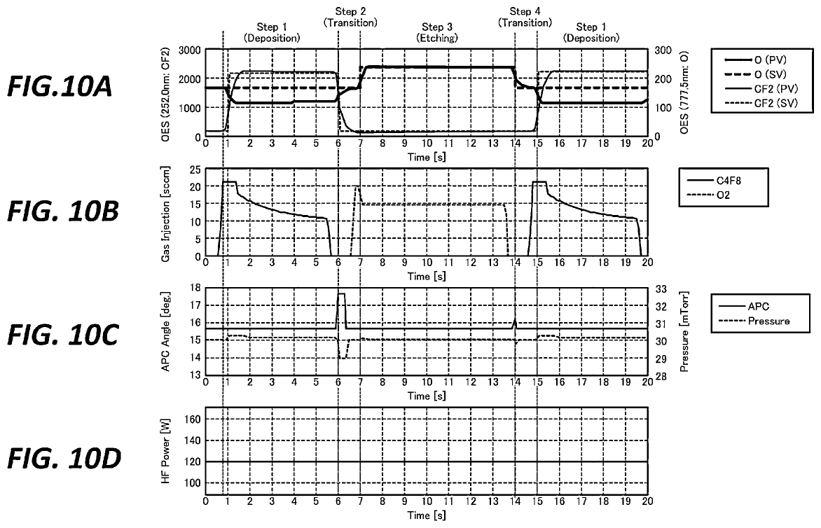

FIGS. 10A to 10D are views illustrating an example of results of optimization implementation of the operation amount U according to the second embodiment. FIGS. 10A to 10D illustrate a case where the optimization of the operation amount U is performed for the ALE process illustrated in FIGS. 9A to 9D.

FIGS. 10A to 10D illustrate steps 1 to 4 of ALE. In FIG. 10A, for the wavelength of 252.0 nm corresponding to C₄F₈ gas and the wavelength of 777.5 nm corresponding to oxygen (O) gas, changes of OES emission intensity setting values SV set in optimization are indicated by dotted lines, respectively. Also, in FIG. 10A, for the wavelength of 252.0 nm corresponding to C₄F₈ gas and the wavelength of 777.5 nm corresponding to the oxygen gas, changes of OES emission intensity observation values PV are indicated by solid lines in a case where ALE is performed with the optimized operation amount U. FIG. 10B illustrates a change of the setting values of gas flow rates of C₄F₈ gas and oxygen gas in the optimized operation amount U. FIG. 10C illustrates a waveform of a change in the opening degree of the APC valve 40b, and a waveform of a change in the pressure within the plasma processing chamber 10 in a case where ALE is performed with the optimized operation amount U. The opening degree of the APC valve 40b is indicated by an angle (APC Angle). FIG. 10D illustrates a waveform of a change in the power (HF Power) of source RF signal (HF) power supplied from the power supply 30 in a case where ALE is performed.

In FIG. 10A, in the step 1, the waveform of the wavelength of 252.0 nm is close to the setting values SV, and is constant. Accordingly, the radical density becomes constant, and thus the process efficiency can be increased.

In the above embodiments, descriptions have been made on an example of a case where the plasma processing apparatus of the present disclosure is a plasma processing system. However, the disclosed technique is not limited to this. The plasma processing apparatus of the present disclosure may be a plasma processing apparatus having another configuration.

In the above embodiments, descriptions have been made on an example of a case where the periodic plasma process is ALE. However, the disclosed technique is not limited to this. The periodic plasma process may be any plasma processing in which supplying of a processing gas to the plasma processing chamber 10, and exhausting of the inside of the plasma processing chamber 10 are periodically repeated. For example, the periodic plasma process may be atomic layer deposition (ALD).

In the above embodiments, descriptions have been made on an example of a case where various parameters, which become coefficients defining processing characteristics of a state space model, such as aₒₑₛ₁ and aₒₑₛ₂ of the matrix A or b_{oes1, gas1} to b_{oes2, gas2} of the matrix B_{gas}, are set as previously adjusted fixed values. However, the disclosed technique is not limited to this. The processor 2a1 may have an adaptive mechanism that removes an error of the state space model. The processor 2a1 updates the parameters of the state space model by the adaptive mechanism. The adaptive mechanism is a control under which parameters are updated based on a residual difference between a prediction value and an actual value during the operation of an actual machine, so that the model error is removed. As for the adaptive mechanism, it is possible to use sequential least squares to which a forgetting coefficient is introduced. For example, the adaptive mechanism can be expressed as in the following equations (26-1) to (26-4). The adaptive gain and the forgetting coefficient are adjusted in advance for each parameter and are appropriately determined.

$$\hat{θ} ( t ) = \hat{θ} ( t - 1 ) + K ( t ) ( y ( t ) - \hat{y} ( t ) ) \qquad ( 26 - 1 )$$

$$\hat{y} ( t ) = {ψ}^{T} ( t ) \hat{θ} ( t - 1 ) \qquad ( 26 - 2 )$$

$$K ( t ) = \frac{P ( t - 1 ) ψ ( t )}{λ + {ψ}^{T} ( t ) P ( t - 1 ) ψ ( t )} \qquad ( 26 - 3 )$$

$$P ( t ) = \frac{( I - K ( t ) {ψ}^{T} ( t ) ) P ( t - 1 )}{λ} \qquad ( 26 - 4 )$$

γ: Observation value (Actual value)
\hat{γ}: Prediction value
λ: Forgetting coefficient
ψ: Operation amount
\hat{θ}: Model parameter (Parameter of state space model)
K: Adaptive gain
P: Variance/covariance matrix

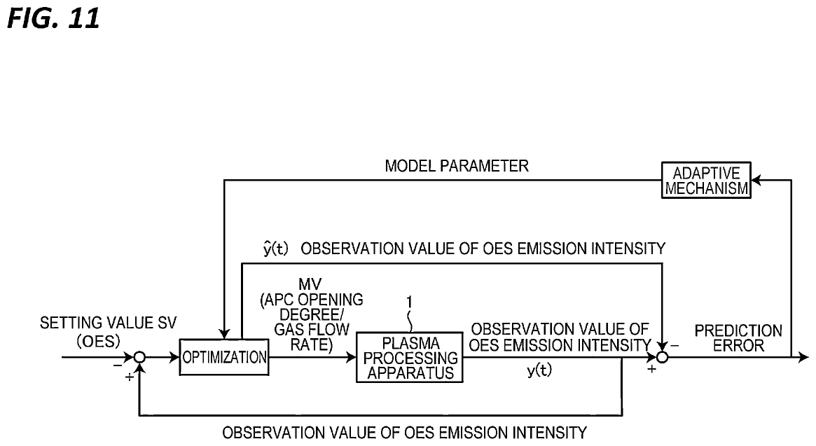

FIG. 11 is a view functionally illustrating the flow of processing of the processor 2a1 according to the second embodiment. In the processor 2a1, as described above, optimization is performed by using the state space model, and the optimum operation amount U is calculated. In the processor 2a1, the plasma processing apparatus 1 is controlled based on the calculated operation amount U. The processor 2a1 updates parameters of the state space model by the adaptive mechanism. For example, the processor 2a1 calculates the prediction value of OES emission intensity by using the state space model. For example, the processor 2a1 calculates a prediction value of OES emission intensity at the current time step from an observation value of OES emission intensity at an immediately preceding time step by using the equation (2). Then, the processor 2a1 calculates a difference between the OES emission intensity observation value obtained from the plasma processing apparatus 1 and the OES emission intensity prediction value, as a prediction error. The processor 2a1 calculates values of parameters of the state space model by using the above-described equations (26-1) to (26-4), and updates the parameters of the state space model to be used for optimization. This can reduce the prediction error of the state space model.

In the above embodiments, descriptions have been made on an example of a case where the disturbance is scavenging. However, the disturbance is not limited to this. Any disturbance may be employed as long as it affects the plasma processing. For example, the disturbance may be a difference between devices or a change with time such as component consumption. Accordingly, the prediction error of the state space model can be reduced even when a disturbance such as a difference between devices or a change with time such as component consumption occurs in the plasma processing apparatus 1.

In the above embodiments, descriptions have been made on an example of a case where processing conditions to be optimized are the flow rate u_{gas1}, the flow rate u_{gas2}, and the APC opening degree u_{apc}. However, the disclosed technique is not limited to this. The processing condition to be optimized may be any processing condition as long as the processing condition can change the OES emission intensity. For example, the processing condition may be the pressure within the plasma processing chamber 10 or the power of high frequency power such as HF or LF. For example, the plasma processing apparatus 1 can change the electron density of plasma by changing the power of high frequency power such as HF or LF, and can control the emission intensity. In the state space model, the vectors u such as the vector u_{gas} and the vector u_{apc} are set as vectors of processing conditions to be optimized, so as to create a model using the processing conditions to be optimized. For example, in the state space model, the vector u may be set as a matrix of HF power, so as to create a model in which the processing condition to be optimized is a vector of HF power. By using such a state space model, it is possible to calculate the optimum operation amount U (vector U) through the method described in the embodiments.

Parameters of the state space model may be changed according to processing conditions or the state of the plasma processing chamber 10. For example, the processor 2a1 may update the state space model according to the pressure within the plasma processing chamber 10, and the power of high frequency power that generates plasma inside the plasma processing chamber 10. The processor 2a1 may calculate the processing conditions by using the updated state space model. For example, the state equation of the state space model can be expressed as in the following equation (27). In the equation (27), B_{gas} and B_{apc} are functions including the pressure p(k), and the power rf(k) of the high frequency power (RF). The power rf(k) of the high frequency power (RF) is power of source RF signal (HF) power used for plasma generation. The state equation of the state space model can be expressed as in the following equation (27):

$$x ( k + 1 ) = Ax ( k ) + {B}_{gas} ( p ( k ) , rf ( k ) ) {u}_{gas} ( k - {n}_{τ , gas} ) + {B}_{apc} ( p ( k ) , rf ( k ) ) {u}_{apc} ( k - {n}_{τ , apc} ) \qquad ( 27 )$$

The equation (27) can be expressed as in following equation (28) for a case of a state equation of OES emission intensities regarding the two gases (gas 1 and gas 2).

$$[ \begin{matrix}{x}_{oes 1} ( k + 1 ) \\ {x}_{oes 2} ( k + 1 )\end{matrix} ] = [ \begin{matrix}{a}_{oes 1} & 0 \\ 0 & {a}_{oes 2}\end{matrix} ] [ \begin{matrix}{x}_{oes 1} ( k ) \\ {x}_{oes 2} ( k )\end{matrix} ] + \qquad ( 28 )$$

$$[ \begin{matrix}{b}_{oes 1 , gas 1} ( p ( k ) , rf ( k ) ) & {b}_{oes 1 , gas 2} ( p ( k ) , rf ( k ) ) \\ {b}_{oes 2 , gas 1} ( p ( k ) , rf ( k ) ) & {b}_{oes 2 , gas 2} ( p ( k ) , rf ( k ) )\end{matrix} ] [ \begin{matrix}{u}_{gas 1} ( k - {n}_{τ , gas} ) \\ {u}_{gas 2} ( k - {n}_{τ , gas} )\end{matrix} ] +$$

$$[ \begin{matrix}{b}_{oes 1 , apc} ( p ( k ) , rf ( k ) ) \\ {b}_{oes 2 , apc} ( p ( k ) , rf ( k ) )\end{matrix} ] {u}_{apc} ( k - {n}_{τ , apc} ) + [ \begin{matrix}{w}_{oes 1 , dv} ( k ) \\ {w}_{oes 2 , dv} ( k )\end{matrix} ]$$

Here,
k is a time step.
p(k) is the pressure within the plasma processing chamber 10 at the time step k.
rf(k) is RF power at the time step k.
p(k) and rf(k) are coefficients to be applied to the operation amount (functions of pressure and RF power).

p(k) and rf(k) are linear regression equations of pressure and RF power, and can be expressed as in the following equation (29):

$$b ( p ( k ) , rf ( k ) ) = ap ( k ) + brf ( k ) + c \qquad ( 29 )$$

Here,

a, b, and c are parameters of the linear regression equation.

The parameters a, b, and c in the equation (29) are determined in advance such that a high correlation with OES emission intensity is obtained.

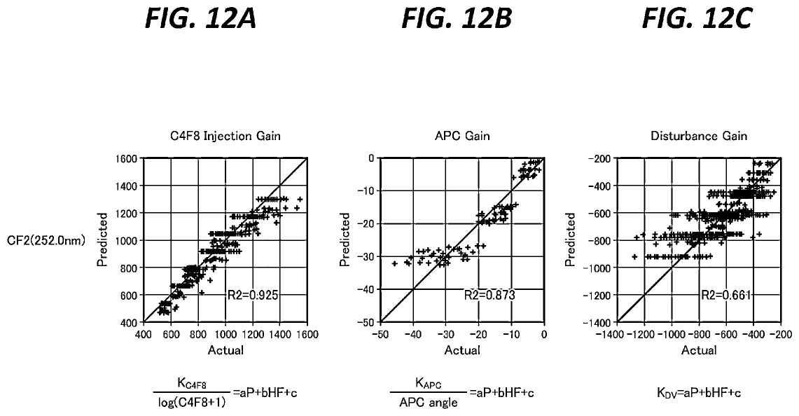

FIGS. 12A to 12C are views illustrating an example of correlation with OES emission intensity. FIGS. 12A to 12C illustrate a case where the parameters a, b, and c are determined such that a high correlation with emission intensity at the wavelength of 252.0 nm corresponding to C₄F₈ gas is obtained. FIG. 12A illustrates a case where the correlation with K_{C4F8}/log(C4F8+1) is obtained. K_{C4F8} is the emission intensity at the wavelength of 252.0 nm, which depends on the supply amount of C₄F₈ gas. C₄F₈ is the supply amount of C₄F₈ gas. FIG. 12B illustrates a case where the correlation with K_{APC}/log(APC_{Angle}) is obtained. K_{APC} is the emission intensity at the wavelength of 252.0 nm, which depends on the opening degree of the APC valve 40b. APC_{Angle} is the angle (APC Angle) of the opening degree of the APC valve 40b. FIG. 12C illustrates a case where the correlation with K_{dv} is obtained. K_{dv} is the amount of change in emission intensity at the wavelength of 252.0 nm, which is caused by the disturbance. As illustrated in FIGS. 12A to 12C, in the equation (29), it is possible to provide correlation by appropriately determining the parameters a, b, and c.

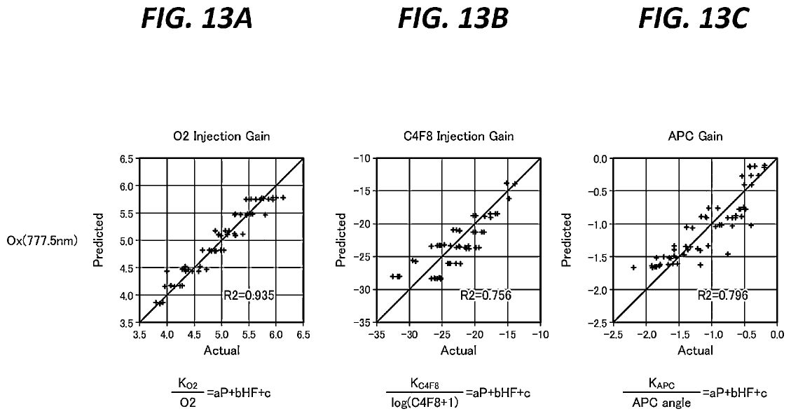

FIGS. 13A to 13C are views illustrating another example of correlation with OES emission intensity. FIGS. 13A to 13C illustrate a case where the parameters a, b, and c are determined such that a high correlation with emission intensity at the wavelength of 777.5 nm corresponding to oxygen gas is obtained. FIG. 13A illustrates a case where the correlation with K_{O2}/log(O2+1) is obtained. K_{O2} is the emission intensity at the wavelength of 777.5 nm, which depends on the supply amount of oxygen (O₂) gas. O2 is the supply amount of O₂ gas. FIG. 13B illustrates a case where the correlation with K_{C4F8}/log(C4F8+1) is obtained. K_{C4F8} is the emission intensity at the wavelength of 777.5 nm, which depends on the supply amount of C₄F₈ gas. C₄F₈ is the supply amount of C₄F₈ gas. FIG. 13C illustrates a case where the correlation with K_{APC}/log(APC_{Angle}) is obtained. K_{APC} is the emission intensity at the wavelength of 777.5 nm, which depends on the opening degree of the APC valve 40b. APC_{Angle} is the angle (APC Angle) of the opening degree of the APC valve 40b.

In such a case, the matrix Gᵤ of the prediction formula illustrated in the equation (4) and the equation (20) can be expressed as in the following equation (30). The matrix Gᵤ illustrated in the equation (30) has long components in each row, and thus each row is divided and some are illustrated in the lower part.

$${G}_{u} = \qquad ( 30 )$$

$$[ \begin{matrix}{B}_{gas} ( {p}_{0} , rf ( 0 ) ) \vert {O}_{2 , 1} & {O}_{2 , 3} & … & {O}_{2 , 2} \vert {B}_{apc} ( {p}_{0} , rf ( 0 ) ) & … & {O}_{2 , 3} \\ {AB}_{gas} ( {p}_{0} , rf ( 1 ) ) \vert {O}_{2 , 1} & {B}_{gas} ( {p}_{0} , f ( 0 ) ) \vert {O}_{2 , 1} & … & {O}_{2 , 2} \vert {AB}_{apc} ( {p}_{0} , rf ( 1 ) ) & … & {O}_{2 , 3} \\ {A}^{2} {B}_{gas} ( {p}_{0} , rf ( 2 ) ) \vert {O}_{2 , 1} & {AB}_{gas} ( {p}_{0} , rf ( 1 ) ) \vert {O}_{2 , 1} & … & {O}_{2 , 2} \vert {A}^{2} {B}_{apc} ( {p}_{0} , rf ( 2 ) ) & … & {O}_{2 , 3} \\ ⋮ & ⋮ & ⋱ & ⋮ & ⋱ & ⋮ \\ \begin{matrix}{A}^{Δ {n}_{τ}} {B}_{gas} ( {p}_{0} , \\ rf ( Δ n \text{?} ) ) \vert {O}_{2 , 1}\end{matrix} & \begin{matrix}{A}^{Δ {n}_{τ} - 1} {B}_{gas} ( {p}_{0} , \\ rf ( Δ n \text{?} - 1 ) ) \vert {O}_{2 , 1}\end{matrix} & … & \begin{matrix}{B}_{gas} ( {p}_{0} , rf ( 0 ) ) \vert \\ {A}^{Δ {n}_{τ}} {B}_{apc} ( {p}_{0} , rf ( Δ n \text{?} ) )\end{matrix} & … & {O}_{2 , 3} \\ ⋮ & ⋮ & ⋱ & ⋮ & ⋱ & ⋮ \\ \begin{matrix}{A}^{m - Δ {n}_{τ} - 1} {B}_{gas} ( {p}_{0} , \\ rf ( m - Δ n \text{?} - 1 ) ) \vert {O}_{2 , 1}\end{matrix} & \begin{matrix}{A}^{m - Δ {n}_{τ} - 2} {B}_{gas} ( {p}_{0} , \\ rf ( m - Δ n \text{?} - 2 ) ) \vert {O}_{2 , 1}\end{matrix} & … & \begin{matrix}{A}^{m - 2 Δ {n}_{τ} - 1} {B}_{gas} ( {p}_{0} , rf ( m - \\ 2 Δ n \text{?} - 1 ) ) \vert \\ {A}^{m - Δ {n}_{τ} - 1} {B}_{apc} ( {p}_{0} , \\ rf ( m - Δ n \text{?} - 1 ) )\end{matrix} & … & {O}_{2 , 2} \vert {B}_{apc} ( {p}_{0} , rf ( 0 ) ) \\ ⋮ & ⋯ & ⋱ & ⋮ & ⋱ & ⋮ \\ \begin{matrix}{A}^{m - 1} {B}_{gas} ( {p}_{0} , \\ rf ( m - 1 ) ) \vert {O}_{2 , 1}\end{matrix} & \begin{matrix}{A}^{m - 2} {B}_{gas} ( {p}_{0} , \\ rf ( m - 2 ) ) \vert {O}_{2 , 1}\end{matrix} & … & \begin{matrix}{A}^{m - {n}_{τ , gas} - 1} {B}_{gas} ( {p}_{0} , \\ rf ( m - n \text{?} - 1 ) ) \vert \\ {A}^{m - 1} {B}_{apc} ( {p}_{0} , rf ( m - 1 ) )\end{matrix} & … & \begin{matrix}{B}_{gas} ( {p}_{0} , rf ( 0 ) ) \vert \\ {A}^{Δ {n}_{τ}} {B}_{apc} ( {p}_{0} , rf ( Δ n \text{?} ) )\end{matrix}\end{matrix} ]$$

$$\text{?} \text{indicates text missing or illegible when filed}$$

p₀ is an actual value.

For rf(k), the setting value of RF power is set from the recipe.

The processor 2a1 updates the state space model according to the pressure within the plasma processing chamber 10, and the power of high frequency power that generates plasma inside the plasma processing chamber 10. Then, the processor 2a1 calculates a processing condition by using the updated state space model. For example, the processor 2a1 updates B_{gas} and B_{apc} at each time step k and calculates the matrix Gᵤ of the equation (20). Then, the processor 2a1 applies the calculated matrix Gᵤ to the equations (25-1) and (25-2) and uses the equations (12-2) and (12-3) as constraint conditions so as to analyze the optimization problem of the equation (12-1) through quadratic programming, and to calculate the operation amount U that minimizes the cost J(U). Accordingly, an optimized vector u is calculated for each element that is not a fixed element in the equation (12-3) of the operation amount U. For example, like in the first embodiment, an optimized vector u is calculated for each element for time steps 5 to 10 in the operation amount U.

Descriptions will be made on an example of results of optimization performed by changing B_{gas}, and B_{apc} in accordance with the timing of HF power, through a comparison with a conventional method.

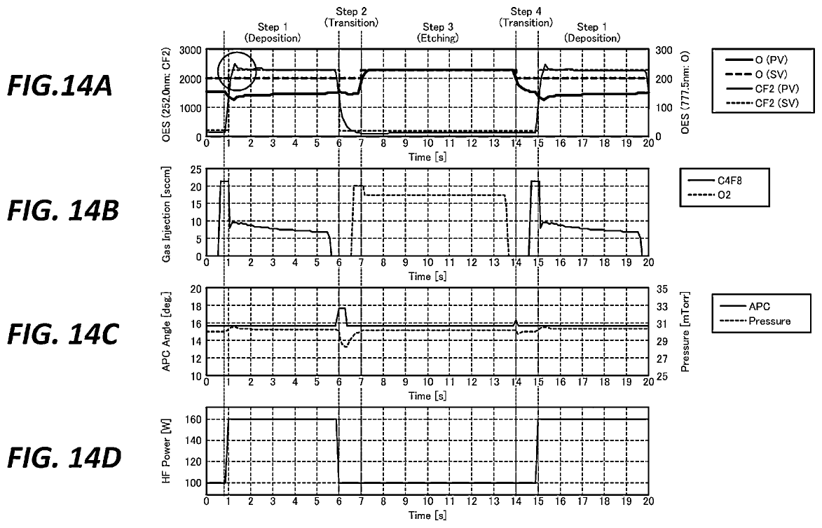

FIGS. 14A to 14D are views illustrating an example of a conventional periodic plasma process. FIGS. 14A to 14D illustrate a case where an etching target film formed on the substrate W is etched by ALE.

FIGS. 14A to 14D illustrate steps 1 to 4 of ALE. In FIG. 14A, for the wavelength of 252.0 nm corresponding to C₄F₈ gas and the wavelength of 777.5 nm corresponding to oxygen (O) gas, changes of OES emission intensity observation values PV are indicated by solid lines, respectively. In FIG. 14A, for the wavelength of 252.0 nm corresponding to C₄F₈ gas and the wavelength of 777.5 nm corresponding to oxygen gas, changes of OES emission intensity setting values SV are indicated by dotted lines, respectively. FIG. 14B illustrates a change of the setting values of gas flow rates of C₄F₈ gas and oxygen gas. FIG. 14C illustrates a waveform of a change in the opening degree of the APC valve 40b, and a waveform of a change in the pressure within the plasma processing chamber 10. The opening degree of the APC valve 40b is indicated by an angle (APC Angle). FIG. 14D illustrates a waveform of a change in the power (HF Power) of source RF signal (HF) power supplied from the power supply 30.

In FIGS. 14A to 14D, in the step 1, overshoot occurs in which the OES emission intensity observation value PV at the wavelength of 252.0 nm, which is indicated by the solid line, exceeds the OES emission intensity setting value SV at the wavelength of 252.0 nm, which is indicated by the dotted line. When overshoot occurs in this manner, it is thought that the plasma process has become inefficient because the radical density deviates from a state of a case where the OES emission intensity is the setting value.

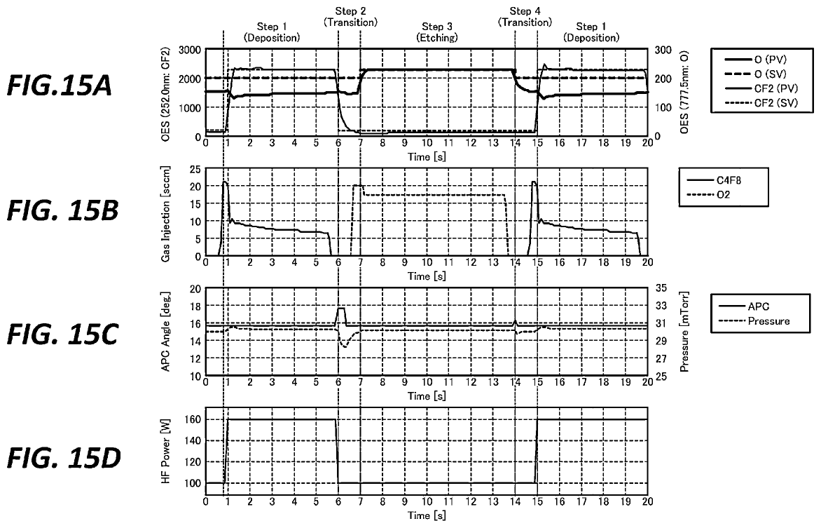

FIGS. 15A to 15D are views illustrating an example of results in a case where the operation amount U is optimized by changing B_{gas} and B_{apc} in accordance with the timing of HF power, in the embodiment. FIGS. 15A to 15D illustrate a case where the optimization of the operation amount U is performed for the ALE process illustrated in FIGS. 14A to 14D.

FIGS. 15A to 15D illustrate steps 1 to 4 of ALE. In FIG. 15A, for the wavelength of 252.0 nm corresponding to C₄F₈ gas and the wavelength of 777.5 nm corresponding to oxygen (O) gas, changes of OES emission intensity setting values SV set in optimization are indicated by dotted lines, respectively. Also, in FIG. 15A, for the wavelength of 252.0 nm corresponding to C₄F₈ gas and the wavelength of 777.5 nm corresponding to oxygen gas, changes of OES emission intensity observation values PV are indicated by solid lines in a case where ALE is performed. FIG. 15B illustrates a change of the setting values of gas flow rates of C₄F₈ gas and oxygen gas. FIG. 15C illustrates a waveform of a change in the opening degree of the APC valve 40b, and a waveform of a change in the pressure within the plasma processing chamber 10 in a case where ALE is performed. The opening degree of the APC valve 40b is indicated by an angle (APC Angle). FIG. 15D illustrates a waveform of a change in the power (HF Power) of source RF signal (HF) power supplied from the power supply 30 in a case where ALE is performed with the optimized operation amount U.

In FIG. 15A, in the step 1, no overshoot occurs, and then the OES emission intensity observation value PV for the wavelength of 252.0 nm, which is indicated by the solid line, is close to the setting value SV indicated by the dotted line. Accordingly, the emission intensity within the plasma processing chamber 10 can be brought close to the setting value of the emission intensity. Accordingly, a plasma control is optimized, and thus, the efficiency of the plasma process can be increased.

In the above embodiments, descriptions have been made on an example of a case where the wavelengths for which emission intensities are detected are wavelengths of 252.0 nm and 777.5 nm. However, the disclosed technique is not limited to this. The wavelengths for which emission intensities are detected may be determined according to radicals to be detected.

In the above embodiments, descriptions have been made on an example of a case where emission intensities of two wavelengths are detected, and then, emission intensities of two types of radicals are acquired, and a processing condition is calculated to bring the emission intensities of two types of radicals closer to setting values, respectively. However, the disclosed technique is not limited to this. Emission intensities of three or more wavelengths may be detected, so that emission intensities of three or more types of radicals may be acquired, and a processing condition may be calculated to bring the emission intensities of three or more types of radicals closer to setting values, respectively. By performing plasma processing under the processing condition calculated in this way, the emission intensities of three or more types of radicals can be brought close to setting values, respectively. Accordingly, the efficiency of the plasma process can be increased because the densities of three or more types of radicals within the plasma processing chamber 10 can be brought close to the state of a case of the setting values of the emission intensities, respectively.

In the above embodiments, descriptions have been made on an example of a case where a state space model is used to perform a predictive control of calculating a processing condition for the next time step. However, the disclosed technique is not limited to this. For the predictive control, for example, other methods such as reinforcement learning or other predictive models may be used.

In the above embodiments, descriptions have been made on an example of a case where the OES emission intensity detected by the sensor 14 is treated as an observation value as it is. However, the disclosed technique is not limited to this. The ratio of the OES emission intensity detected by the sensor 14 to the OES emission intensity of a reference wavelength (e.g., OES emission intensity of Ar) may be obtained, and the value of the ratio may be used as the observation value.

So far, embodiments have been described. As above, the plasma processing method according to the embodiment includes the steps (a), (b), and (c). In the step (a), in plasma processing in which supplying of a processing gas to the plasma processing chamber 10 (a chamber) and exhausting of inside of the plasma processing chamber 10 are periodically repeated, emission intensity of radicals generated by ionization of the processing gas within the plasma processing chamber 10 is acquired by the sensor 14 that detects emission intensity within the plasma processing chamber 10. In the step (b), a target setting value of the emission intensity is acquired. In the step (c), a processing condition of the plasma processing which brings the emission intensity closer to the setting value is calculated, based on the emission intensity acquired by the step (a) and the setting value acquired by the step (b). By performing the plasma processing under the processing condition calculated in this manner, the emission intensity can be brought close to the setting value. Accordingly, the plasma processing method according to the embodiment can increase the efficiency of the plasma process because the radical density within the plasma processing chamber 10 can be brought close to the state of a case of the setting value of the emission intensity.

In the step (a), a gas flow rate of the processing gas supplied to the plasma processing chamber 10 and an APC opening degree (an operation amount) of the APC valve 40b (an adjuster) that adjusts an exhaust volume of the plasma processing chamber 10 are further acquired. In the step (c), the processing condition is calculated based on the emission intensity, the gas flow rate, and the APC opening degree acquired by the step (a), and the setting value acquired by the step (b). By performing the plasma processing under the processing condition calculated in this manner, the emission intensity can be brought close to the setting value. Accordingly, the plasma processing method according to the embodiment can increase the efficiency of the plasma process because the radical density within the plasma processing chamber 10 can be brought close to the state of a case of the setting value of the emission intensity.

In the step (c), as for the processing condition, the gas flow rate of the processing gas to be supplied to the plasma processing chamber 10 and the APC opening degree of the APC valve 40b are calculated. By performing the plasma processing with the calculated gas flow rate and APC opening degree, the emission intensity can be brought close to the setting value. Accordingly, the plasma processing method according to the embodiment can increase the efficiency of the plasma process because the radical density within the plasma processing chamber 10 can be brought close to the state of a case of the setting value of the emission intensity.

In the step (c), as for the processing condition, power of high frequency power to be supplied to the plasma processing chamber 10 is calculated. By performing the plasma processing with the calculated power of high frequency power, the emission intensity can be brought close to the setting value. Accordingly, the plasma processing method according to the embodiment can increase the efficiency of the plasma process because the electron density within the plasma processing chamber 10 can be brought close to the state of a case of the setting value of the emission intensity.

In the step (c), a state space model is used to calculate the processing condition. Accordingly, in the plasma processing method according to the embodiment, it is possible to calculate the processing condition that brings the emission intensity closer to the setting value.

In the step (c), the state space model is updated according to the pressure within the plasma processing chamber 10, and the power of high frequency power that generates plasma inside the plasma processing chamber 10, and the updated state space model is used to calculate the processing condition. Accordingly, in the plasma processing method according to the embodiment, the emission intensity within the plasma processing chamber 10 can be brought close to the setting value of the emission intensity. This optimizes the plasma control, so that the efficiency of the plasma process can be increased.

The plasma processing method according to the embodiment further includes the step (d). In the step (d), the state space model is updated based on a difference between an emission intensity prediction value calculated by using the state space model and the emission intensity obtained by the sensor 14. Accordingly, in the plasma processing method according to the embodiment, a prediction error of the state space model can be reduced.

The state space model includes a model of disturbance occurring in the plasma processing chamber 10. Accordingly, the plasma processing method according to the embodiment can increase the efficiency of the plasma process because even if a disturbance occurs, the radical density within the plasma processing chamber 10 can be brought close to the state of a case of the setting value of the emission intensity.

In the step (a), emission intensities of two or more types of radicals are acquired. In the step (b), target setting values of respective emission intensities of the two or more types of radicals are acquired. In the step (c), the processing condition, which brings the emission intensities of the two or more types of radicals closer to the setting values, respectively, is calculated. By performing the plasma processing under the calculated processing condition, the emission intensities of two or more types of radicals can be brought close to setting values, respectively. Accordingly, the plasma processing method according to the embodiment can increase the efficiency of the plasma process because the densities of two or more types of radicals within the plasma processing chamber 10 can be brought close to the state of a case of the setting values of the emission intensities, respectively.

The plasma processing method according to the embodiment further includes the step (e). In the step (c), the processing condition is calculated at each time step of a predetermined period. In the step (e), at each time step, the plasma processing is controlled by using the processing condition calculated by the step (c). Accordingly, the plasma processing method according to the embodiment can increase the efficiency of the plasma process because the radical density within the plasma processing chamber 10 can be brought close to the state of a case of the setting value of the emission intensity. In the step (c), at each time step, over a plurality of time steps subsequent to the time step, the processing conditions are calculated for the time steps, respectively. In the step (d), among the respective processing conditions of the time steps calculated by the step (c), the processing condition of the earliest time step is used to control the plasma processing. Accordingly, in the plasma processing method according to the embodiment, it is possible to control the plasma processing in consideration of the plurality of subsequent time steps.

The plasma processing apparatus 1 according to the embodiment includes the gas supply 20 (a supply), the exhaust device 104 (an exhaust unit), the sensor 14, and the controller 2. The gas supply 20 is configured to supply a processing gas to the plasma processing chamber 10. The exhaust device 104 is provided with the APC valve 40b (an adjuster) that adjusts an exhaust volume of the plasma processing chamber 10, and is configured to exhaust a gas inside the plasma processing chamber 10. The sensor 14 is configured to detect emission intensity within the plasma processing chamber 10. The controller 2 is configured to perform plasma processing in which supplying of the processing gas to the plasma processing chamber 10 by the gas supply 20, and exhausting of inside of the plasma processing chamber 10 by the exhaust device 104 are periodically repeated. The controller 2 acquires an emission intensity of radicals generated by ionization of the processing gas within the plasma processing chamber 10, by the sensor 14, acquires a target setting value of the emission intensity, and calculates a processing condition of the plasma processing which brings the emission intensity closer to the setting value based on the acquired emission intensity and the acquired setting value. Accordingly, the plasma processing apparatus 1 according to the embodiment can increase the efficiency of the plasma process because the radical density within the plasma processing chamber 10 can be brought close to the state of a case of the setting value of the emission intensity.

Additionally, the following appendixes are further disclosed regarding the embodiments.

### (Appendix 1)

A plasma processing method including:
(a) acquiring emission intensity of radicals generated by ionization of a processing gas within a chamber by a sensor that detects emission intensity within the chamber, in a plasma processing in which supplying of the processing gas to the chamber and exhausting of inside of the chamber are periodically repeated;
(b) acquiring a target setting value of the emission intensity: and
(c) calculating a processing condition of the plasma processing which brings the emission intensity closer to the setting value, based on the emission intensity acquired by (a) and the setting value acquired by (b).

### (Appendix 2)

The plasma processing method described in Appendix 1, in which in (a), a gas flow rate of the processing gas supplied to the chamber and an operation amount of an adjuster that adjusts an exhaust volume of the chamber are further acquired, and

in c), the processing condition is calculated based on the emission intensity, the gas flow rate, and the operation amount acquired by (a), and the setting value acquired by (b).

### (Appendix 3)

The plasma processing method described in Appendix 2, in which in (c), the gas flow rate of the processing gas to be supplied to the chamber and the operation amount of the adjuster are calculated as the processing condition.

### (Appendix 4)

The plasma processing method described in Appendix 1 or 2, in which in (c), power of radio-frequency power to be supplied to the chamber is calculated as the processing condition.

### (Appendix 5)

The plasma processing method described in any one of Appendixes 1 to 4, in which in (c), a state space model is used to calculate the processing condition.

### (Appendix 6)

The plasma processing method described in Appendix 5, in which in (c), the state space model is updated according to a pressure within the chamber, and the power of the radio-frequency power that generates plasma inside the chamber, and the updated state space model is used to calculate the processing condition.

### (Appendix 7)

The plasma processing method described in Appendix 5, further including:

(d) updating the state space model based on a difference between an emission intensity prediction value calculated by using the state space model and the emission intensity obtained by the sensor.

### (Appendix 8)

The plasma processing method described in any one of Appendixes 5 to 7, in which the state space model includes a model of disturbance occurring in the chamber.

### (Appendix 9)

The plasma processing method described in any one of Appendixes 1 to 8, in which in (a), emission intensities of two or more types of radicals are acquired,
in (b), target setting values of the emission intensities of the two or more types of radicals are acquired, respectively, and
in (c), the processing condition, which brings the emission intensities of the two or more types of radicals closer to the setting values, respectively, is calculated.

### (Appendix 10)

The plasma processing method described in any one of Appendixes 1 to 9, in which in (c), the processing condition is calculated at each time step of a predetermined period, and
the plasma processing method further includes:
(e) controlling, at each time step, the plasma processing by using the processing condition calculated by (c).

### (Appendix 11)

The plasma processing method described in Appendix 10, in which in (c), at each time step, the processing condition for each time step is calculated from the time step to a plurality of time steps ahead, and

in (e), among the respective processing conditions of the time steps calculated by (c), the processing condition of an earliest time step is used to control the plasma processing.

### (Appendix 12)

A plasma processing apparatus including:
a supply configured to supply a processing gas to a chamber;
an exhauster provided with an adjuster that adjusts an exhaust volume of the chamber, and configured to exhaust gases inside the chamber;
a sensor configured to detect an emission intensity within the chamber; and
a controller configured to perform a plasma processing in which supplying of the processing gas to the chamber by the supply and exhausting of inside of the chamber by the exhauster are periodically repeated,
wherein the controller
acquires an emission intensity of radicals generated by ionization of the processing gas within the chamber, by the sensor,
acquires a target setting value of the emission intensity, and
calculates a processing condition of the plasma processing which brings the emission intensity closer to the setting value based on the acquired emission intensity and the acquired setting value.

According to the present disclosure, the efficiency of a plasma process can be increased.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A plasma processing method comprising:
(a) acquiring emission intensity of radicals generated by ionization of a processing gas within a chamber by a sensor that detects emission intensity within the chamber, in a plasma processing in which supplying of the processing gas to the chamber and exhausting of inside of the chamber are periodically repeated;
(b) acquiring a target setting value of the emission intensity; and
(c) calculating a processing condition of the plasma processing which brings the emission intensity closer to the setting value, based on the emission intensity acquired by (a) and the setting value acquired by (b).

2. The plasma processing method according to claim 1, wherein in (a), a gas flow rate of the processing gas supplied to the chamber and an operation amount of an adjuster that adjusts an exhaust volume of the chamber are further acquired, and
in (c), the processing condition is calculated based on the emission intensity, the gas flow rate, and the operation amount acquired by (a), and the setting value acquired by (b).

3. The plasma processing method according to claim 2, wherein in (c), the gas flow rate of the processing gas to be supplied to the chamber and the operation amount of the adjuster are calculated as the processing condition.

4. The plasma processing method according to claim 1, wherein in (c), power of radio-frequency power to be supplied to the chamber is calculated as the processing condition.

5. The plasma processing method according to claim 1, wherein in (c), a state space model is used to calculate the processing condition.

6. The plasma processing method according to claim 5, wherein in (c), the state space model is updated according to a pressure within the chamber, and the power of the radio-frequency power that generates plasma inside the chamber, and the updated state space model is used to calculate the processing condition.

7. The plasma processing method according to claim 5, further comprising:
(d) updating the state space model based on a difference between an emission intensity prediction value calculated by using the state space model and the emission intensity obtained by the sensor.

8. The plasma processing method according to claim 5, wherein the state space model includes a model of disturbance occurring in the chamber.

9. The plasma processing method according to claim 1, wherein in (a), emission intensities of two or more types of radicals are acquired,
in (b), target setting values of the emission intensities of the two or more types of radicals are acquired, respectively, and
in (c), the processing condition, which brings the emission intensities of the two or more types of radicals closer to the setting values, respectively, is calculated.

10. The plasma processing method according to claim 1, wherein in (c), the processing condition is calculated at each time step of a predetermined period, and
the plasma processing method further comprises:
(e) controlling, at each time step, the plasma processing by using the processing condition calculated by (c).

11. The plasma processing method according to claim 10, wherein in (c), at each time step, the processing condition for each time step is calculated from the time step to a plurality of time steps ahead, and
in (e), among the respective processing conditions of the time steps calculated by (c), the processing condition of an earliest time step is used to control the plasma processing.

12. A plasma processing apparatus comprising:
a supply configured to supply a processing gas to a chamber;
an exhauster provided with an adjuster that adjusts an exhaust volume of the chamber, and configured to exhaust gases inside the chamber;
a sensor configured to detect an emission intensity within the chamber; and
a controller configured to perform a plasma processing in which supplying of the processing gas to the chamber by the supply and exhausting of inside of the chamber by the exhauster are periodically repeated,
wherein the controller
acquires an emission intensity of radicals generated by ionization of the processing gas within the chamber, by the sensor,
acquires a target setting value of the emission intensity, and
calculates a processing condition of the plasma processing which brings the emission intensity closer to the setting value based on the acquired emission intensity and the acquired setting value.
